(19) United States
(12) Patent Application Publication
(10) Pub. No.: US 2024/0234316 A9
(43) Pub. Date: Jul. 11, 2024

(54) Local VDD And VSS Power Supply Through Dummy Gates with Gate Tie-Downs and Associated Benefits

(71) Applicant: International Business Machines Corporation, Armonk, NY (US)

(72) Inventors: Ruilong Xie, Niskayuna, NY (US); Nicholas Anthony Lanzillo, Wynantskill, NY (US); Lawrence A. Clevenger, Saratoga Springs, NY (US); Hosadurga Shobha, Niskayuna, NY (US); Huai Huang, Clifton Park, NY (US)

(21) Appl. No.: 17/969,260

(22) Filed: Oct. 19, 2022

(51) Int. Cl. H01L 23/528; H01L 21/8238; H01L 23/522; H01L 27/092; H01L 29/08; H01L 29/40; H01L 29/417; H01L 29/423; H01L 29/66; H01L 29/775

(52) U.S. Cl. CPC H01L 23/5286; H01L 21/823814; H01L 21/823871; H01L 23/5226; H01L 27/092; H01L 29/0847; H01L 29/401; H01L 29/41733; H01L 29/41775; H01L 29/42392; H01L 29/66439; H01L 29/66545; H01L 29/775; H01L 29/0673

(57) ABSTRACT

An integrated circuit structure includes a power supply rail formed in a backside of a semiconductor wafer. The integrated circuit structure also includes a frontside BEOL wire layer connected to the power supply rail through a gate, wherein the gate is of a type to be powered off by a power supply coupled through the gate from the power supply rail to the first frontside BEOL wire layer. A method of forming an integrated circuit structure includes forming a power supply rail in a backside of a semiconductor wafer, forming a gate in the semiconductor wafer, and forming a frontside BEOL wire layer connected to the power supply rail through the gate. Again, the gate is of a type to be powered off by a power supply coupled through the gate from the power supply rail to the first frontside BEOL wire layer.

### BACKGROUND

This invention generally relates to semiconductors and, more specifically, relates to local VDD and VSS power supply through dummy gates with gate tie-down.

In semiconductor devices formed using a backside power distribution network (BSPDN), there are some areas that could be improved. For instance, a source/drain (S/D) epitaxial silicon (epi) area may have to connect to the backside through a via-to-buried power rail (VBPR). As another example and because of the VBPR, another S/D epitaxial silicon area may only access one signal track above (e.g., near the back end of line, BEOL, area).

Concerning the VBPR and similar technologies, consider Divya Prasad, et al., “Buried Power Rails and Back-side Power Grids: Arm CPU Power Delivery Network Design Beyond 5 nm”, 2019 IEEE International Electron Devices Meeting (IEDM), which states the following about a Power Delivery Network (PDN): “To remove the overhead of power tap cells and the whole PDN, altogether, from the front side (which decouples the sharing of wiring resources between signals and power delivery), 3D integration techniques have been proposed to implement a back-side PDN where power is delivered using a small (‘micro’) Through-Silicon-Via (μTSV) that lands on the buried rail.” Multiple technologies are explored: “Three power-rail technologies are explored in this study”, “namely, the traditional Front-Side (FS) PDN, Front-Side with Buried-Power-Rails (FS-BPR) and Back-Side power delivery with Buried-Power-Rails (BS-BPR).” The FS-BPR and BS-BPR do not address the above issues and require a lot of extra processing steps.

### SUMMARY

This section is meant to be exemplary and not meant to be limiting.

In an exemplary embodiment, an integrated circuit structure includes a power supply rail formed in a backside of a semiconductor wafer, and a frontside back end of line (BEOL) wire layer connected to the power supply rail through a gate. The gate is of a type to be powered off by a power supply coupled through the gate from the power supply rail to the first frontside BEOL wire layer. This provides power and/or ground access at the frontside BEOL wire layer without using a via-to-backside power rail, which frees space to allow certain source/drain (S/D) epitaxial regions to contact multiple signal tracks, one of which can be in an area not currently accessed, and also allows other S/D regions to be powered from tracks above the regions. Manufacturing is also minimally impacted, and this technique can be combined with current techniques, each used on different locations of the semiconductor wafer so that both conventional and new structures can be used on the same wafer.

Another example is an integrated circuit structure according to the previous wherein the gate is a first gate and the power supply rail is a first power supply rail. The integrated circuit structure further includes: a second power supply rail formed in the backside of the semiconductor wafer; and another frontside BEOL wire layer connected to the second power supply rail through a second gate, wherein the second gate is of a type to be powered off by a power supply coupled through the second gate from the second power supply rail to the other frontside BEOL wire layer. This allows multiple routings of power supplies to the frontside BEOL wire layer.

A further example is the integrated circuit structure according to the previous paragraph, wherein the first gate is an n-type gate and the power supply for the first gate is ground; and the second gate is a p-type gate, and the power supply for the first gate is power. Furthermore, the first and second gates may be formed adjacent to each other and isolated at least by a gate cut formed between the adjacent first and second gates. This allows both power and ground to be routed to frontside BEOL wire layers, e.g., using adjacent gates.

Another example is the integrated circuit structure, further comprising a frontside BEOL wire that is connected to one or more source/drain epitaxy silicon areas of corresponding transistors. An additional example is the integrated circuit structure according to the previous sentence, wherein the frontside BEOL wire is connected to the one or more source/drain epitaxy silicon areas of corresponding transistors using corresponding one or more vias. An additional example is the integrated circuit structure according to the first sentence of this paragraph, wherein the frontside BEOL wire layer is connected to the frontside BEOL wire. What these provide are the ability for a source/drain region to access multiple signal tracks, including one in N2N (n-type to n-type) semiconductor areas or in P2P (p-type to p-type) semiconductor areas, and another in NFET or PFET (respectively) areas.

A further example is a method of forming an integrated circuit structure, comprising the following: forming a power supply rail in a backside of a semiconductor wafer; forming a gate in the semiconductor wafer; and forming a frontside back end of line (BEOL) wire layer connected to the power supply rail through the gate, wherein the gate is of a type to be powered off by a power supply coupled through the gate from the power supply rail to the first frontside BEOL wire layer. This provides power and/or ground access at the frontside BEOL wire layer without using a via-to-backside power rail, which frees space to allow certain source/drain (S/D) epitaxial regions to contact multiple signal tracks, one of which can be in an area not currently accessed, and also allows other S/D regions to be powered from tracks above the regions. Manufacturing is also minimally impacted, and this technique can be combined with current techniques, each used on different locations of the semiconductor wafer so that both conventional and new structures can be used on the same wafer.

Another example is a method according to the previous paragraph, wherein: forming the gate in the semiconductor wafer further comprises forming multiple gates on a substrate of the semiconductor wafer, wherein forming the multiple gates comprises: performing gate patterning to pattern multiple gates on a substrate, of which the gate is one; performing source/drain epitaxy to form source/drain regions for the multiple gates; performing interlayer dielectric deposition to cover at least the source/drain regions and at least partially isolating the multiple gates; and forming a frontside back end of line (BEOL) wire layer comprises forming BEOL interconnects and bonding a carrier wafer to the substrate on which the multiple gates have been formed.

A further method includes the method of the previous paragraph, wherein: forming the gate in the semiconductor wafer further comprises forming a backside gate-tie-down via at an edge of the gate and filling the backside gate-tie-down via with conductive material at a same time conductive material forming the gate is formed; the method further comprises forming a gate via contact to connect the gate having the gate-tie-down via to the frontside back end of line (BEOL) wire layer; and the method further comprises further comprises connecting the power supply rail to the gate-tie-down via.

Another exemplary method further comprises forming a source/drain contact contacting a corresponding source/drain region and extending beyond the source/drain region to provide access to one of a signal track that is in a region between two doped regions of the same type and a signal track that is within the doped region.

What these provide are the ability for a source/drain region to access multiple signal tracks, including one in N2N (n-type to n-type) semiconductor areas or P2P (p-type to p-type) semiconductor areas, and another in NFET or PFET (respectively) areas.

Another method further comprises connecting one or more source/drain regions of corresponding one or more others of the multiple gates which need power supplies to one or more corresponding frontside BEOL wires, the one or more corresponding frontside BEOL wires connected to the frontside back end of line (BEOL) wire layer.

A further method includes a method wherein: the gate is a first gate and the power supply rail is a first power supply rail; the method further comprises: forming a second power supply rail formed in the backside of the semiconductor wafer; and forming another frontside BEOL wire layer connected to the second power supply rail through a second gate, wherein the second gate is of a type to be powered off by a power supply coupled through the second gate from the second power supply rail to the other frontside BEOL wire layer; the first gate is an n-type gate and the power supply for the first gate is ground; and the second gate is a p-type gate, and the power supply for the first gate is power.

A further method includes the method of the previous paragraph, but wherein forming the first and second gates comprise forming the first and second gates adjacent to each other and the method comprises forming and filling a gate cut between the adjacent first and second gates.

These examples provide power and/or ground access at the frontside BEOL wire layer without using a via-to-backside power rail, which frees space to allow certain source/drain (S/D) epitaxial regions to contact multiple signal tracks, one of which can be in an area not currently accessed, and also allows other S/D regions to be powered from tracks above the regions.

Furthermore, these methods may be combined with current techniques, each used on different locations of the semiconductor wafer, e.g., meaning current designs do not have to be modified to implement the current improvements.

### BRIEF DESCRIPTION OF THE SEVERAL VIEWS OF THE DRAWINGS

FIG. 1A is an example of a conventional POR integrated circuit structure, while FIG. 1B is an example of an integrated circuit structure of an exemplary embodiment herein;

FIGS. 2A, 2B, and 2C are different cross-sectional views X, Y1, and Y2, respectively, of an integrated circuit structure after NS and STI formation, while FIG. 2D illustrates a top view layout of the integrated circuit structure and indicates where the cross-sectional views X, Y1, and Y2 are in the layout;

FIGS. 3A, 3B, and 3C are different cross-sectional views X, Y1, and Y2, respectively, of the integrated circuit structure after OPL deposition and patterning and gate tie-down opening formation, while FIG. 3D illustrates a top view layout of the integrated circuit structure and indicates where the cross-sectional views X, Y1, and Y2 are in the layout;

FIGS. 4A, 4B, and 4C are different cross-sectional views X, Y1, and Y2, respectively, of the integrated circuit structure after OPL/HM removal, dummy gate formation, SiGe55 removal, BDI/spacer formation, NS recess, inner spacer formation, S/D epi formation, ILD deposition and CMP, while FIG. 4D illustrates a top view layout of the integrated circuit structure and indicates where the cross-sectional views X, Y1, and Y2 are in the layout;

FIGS. 5A, 5B, and 5C are different cross-sectional views X, Y1, and Y2, respectively, of the integrated circuit structure after gate cut formation, while FIG. 5D illustrates a top view layout of the integrated circuit structure and indicates where the cross-sectional views X, Y1, and Y2 are in the layout;

FIGS. 6A, 6B, and 6C are different cross-sectional views X, Y1, and Y2, respectively, of the integrated circuit structure after dummy gate removal, SiGe release, and replacement HKMG formation, while FIG. 6D illustrates a top view layout of the integrated circuit structure and indicates where the cross-sectional views X, Y1, and Y2 are in the layout;

FIGS. 7A, 7B, and 7C are different cross-sectional views X, Y1, and Y2, respectively, of the integrated circuit structure after MOL processing, and lower BEOL formation with VDD/VSS local supply from a dummy gate tie-down;

FIGS. 8A, 8B, and 8C are different cross-sectional views X, Y1, and Y2, respectively, of the integrated circuit structure after forming more BEOL levels and bonding a carrier wafer;

FIGS. 9A, 9B, and 9C are different cross-sectional views X, Y1, and Y2, respectively, of the integrated circuit structure after a wafer flip, substrate removal, and stopping on the etch stop layer;

FIGS. 10A, 10B, and 10C are different cross-sectional views X, Y1, and Y2, respectively, of the integrated circuit structure after etch stop layer removal and remaining Si removal;

FIGS. 11A, 11B, and 11C are different cross-sectional views X, Y1, and Y2, respectively, of the integrated circuit structure after backside ILD formation, and backside power rail formation;

FIGS. 12A, 12B, and 12C are different cross-sectional views X, Y1, and Y2, respectively, of the integrated circuit structure after forming a backside power distribution network layer;

FIG. 13A is an example of a conventional POR integrated circuit structure, while FIG. 13B is an example of an integrated circuit structure of an exemplary embodiment herein; and

FIG. 14 provides a detailed top-down layout on S/D contact, VBPR, and VAs.

### DETAILED DESCRIPTION

Abbreviations that may be found in the specification and/or the drawing figures are defined below, at the end of the detailed description section.

The word “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

The instant disclosure concerns the front-end-of-line (FEOL), the middle-of-line (MOL) and the back-end-of-line (BEOL). An introduction to these concepts is now presented. The FEOL covers the processing of the active parts of the chips, i.e., the transistors that reside on the bottom of the chip. The BEOL, the final stage of processing, refers to the metal layer interconnects that reside in the top part of the chip. The FEOL and the BEOL are tied together by the MOL. The MOL is typically made up of metal structures that serve as contacts to the transistor's source, drain, and gate. These structures connect to the local interconnect layers of the BEOL.

The architectures that make up the FEOL may include gate-all-around (GAA) nanosheet, forksheet, and complementary field effect transistor (CFET) devices. The architectures of these devices impact the local interconnect layers, calling for different BEOL materials (such as ruthenium (Ru), molybdenum (Mo), and metal alloys) and various integration schemes (such as hybrid metallization, semi-damascene, and hybrid-height with zero via structures). Vias-to-backside-power-rail (VBPRs) are part of the power delivery network and may be used in MOL to wire some terminals of the transistors to backside power distribution network as help to reduce the congestion in lower BEOL.

Now that an introduction to the FEOL, the MOL, and the BEOL has been provided, as stated above, in semiconductor devices formed using a backside power distribution network (BSPDN), there are some areas that could be improved. These are shown via a figure, described below, but the following are issues with conventional techniques: a source/drain (S/D) epitaxial silicon (epi) area may have to connect to the backside through a via-to-backside power rail (VBPR); and/or another S/D epitaxial silicon area may only access one signal track above (e.g., near the back end of line, BEOL, area). Further, there is typically no access to a signal track in N2N or P2P regions. Thus, a gate tie-down to backside power rail offers opportunity to re-design the routings locally by power supply from dummy gates with a gate tie-down. These issues are addressed herein, and figures of semiconductor devices illustrating a conventional POR (process of record) are described.

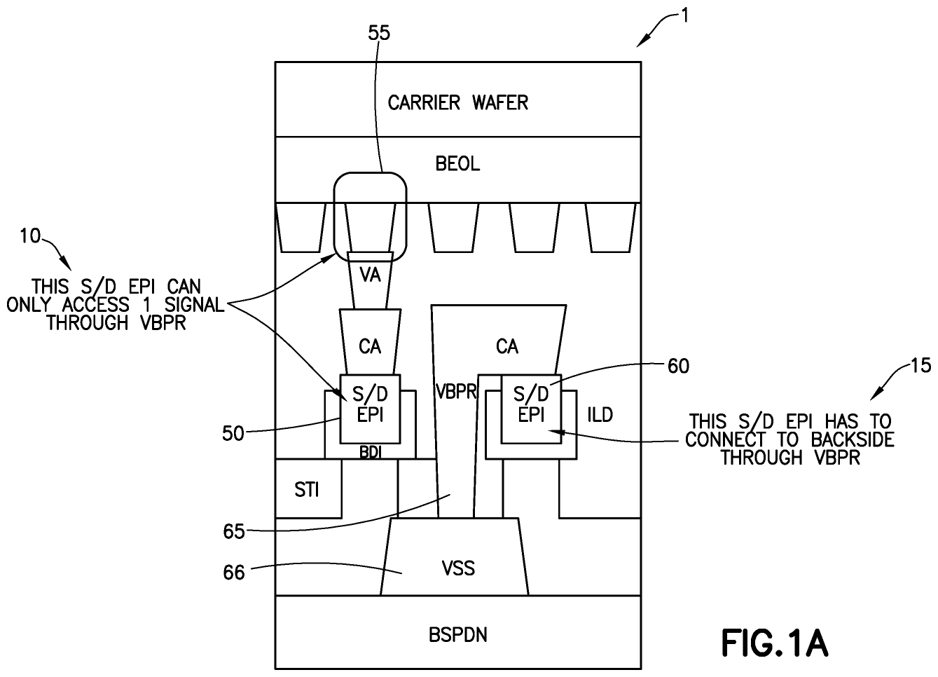

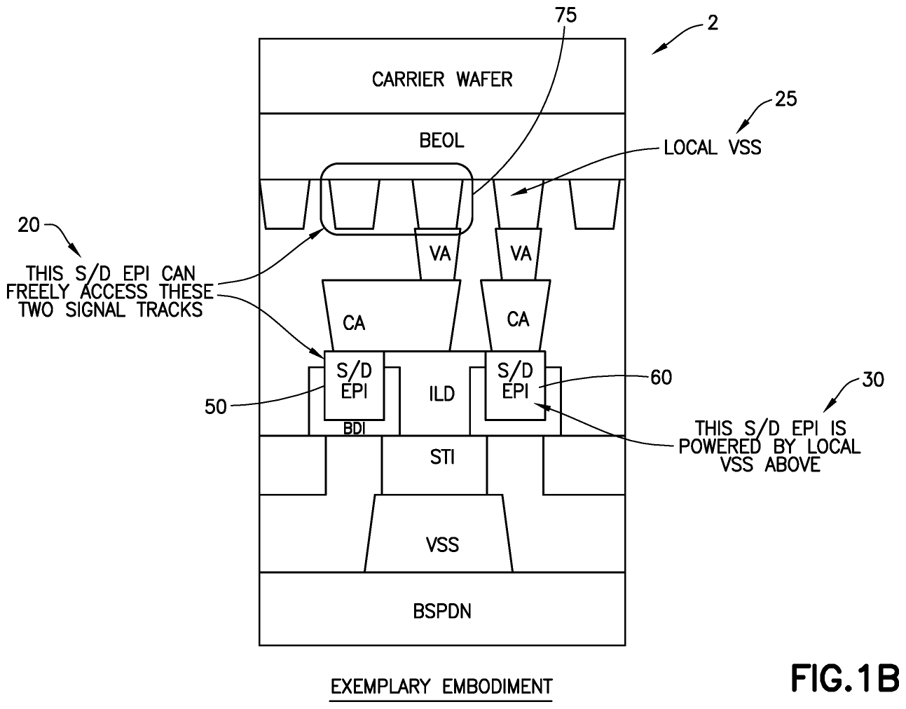

Consider FIG. 1A, which is an example of a conventional POR integrated circuit structure 1. As illustrated by reference 10, the S/D epi (epitaxial silicon area) 50 has access to only one (1) signal track 55 above (e.g., near the BEOL layer). As indicated by reference 15, the S/D epi area 60 has to connect to the backside through the VBPR 65, which is connected to the VSS area 66. Due to the presence of the VBPR at the cell boundary (between S/D epi 50 and 60), the source/drain contact (CA) over S/D epi 50 can't freely extend to cell boundary region to access other signal tracks above.

By contrast, FIG. 1B is an example of an integrated circuit structure 2 of an exemplary embodiment herein. As indicated by reference 20, the S/D epi 50 can freely access the two signal tracks indicated by reference 75. The track shown as being connected to signal line using via VA and contact CA is within an N2N or P2P region. As indicated by reference 30, the S/D epi 60 is powered by local VSS 25 from above.

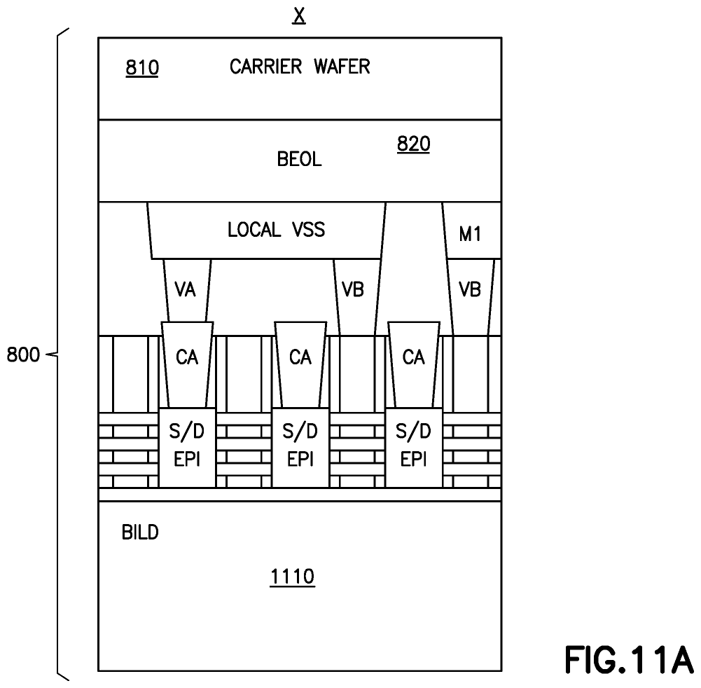

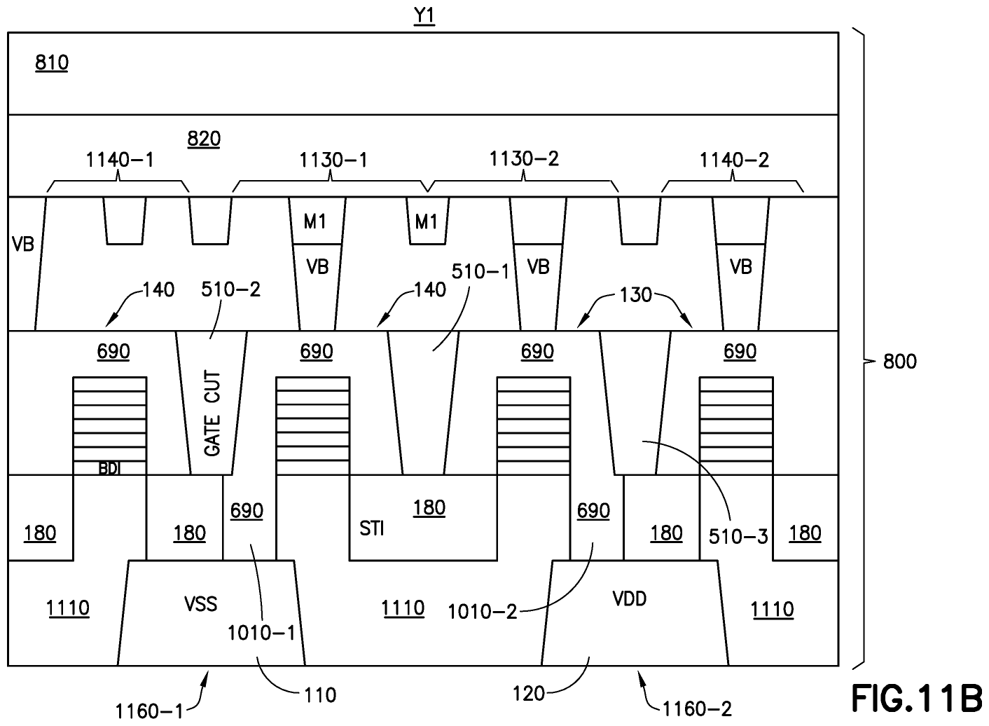

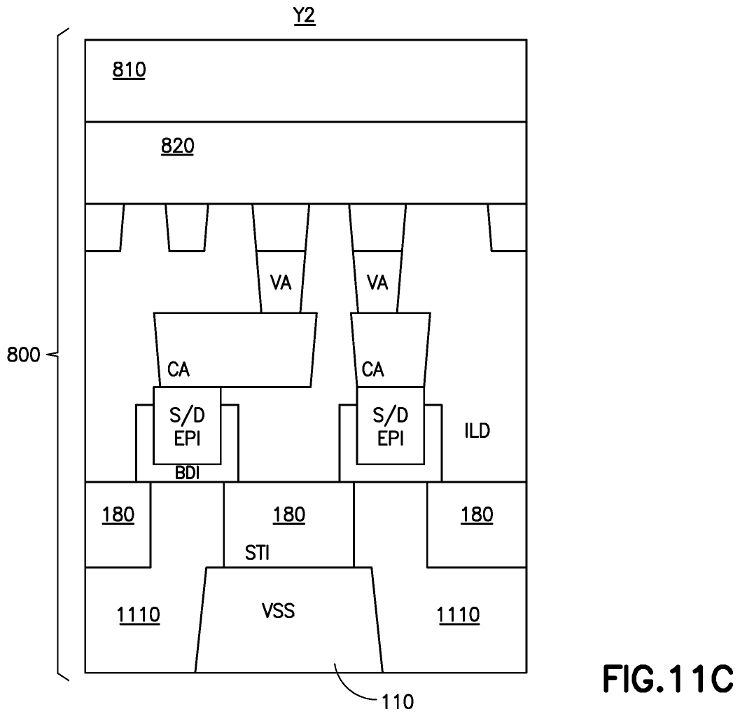

Techniques to remove the VBPR for one or both of VDD or VSS are described herein, but include forming and using a “dummy” gate to provide a bridge from a power supply rail in the backside to the frontside BEOL wiring. This is described in much more detail below, but such dummy gates 1130 can be seen at least in FIG. 11B. The “dummy” gate is a gate that is turned off and not used as an active gate. Thus, the benefits described in the previous paragraph are enabled by the dummy gate(s) described in this paragraph (and in much more detail below).

Furthermore, there are advantages in manufacturing. One such advantage is that multiple gates are already being formed, so there are only a few extra steps to create a gate or gates with corresponding gate tie downs, which then provide the benefits as described above and herein.

Additionally, the techniques herein are fully compatible with the POR process (e.g., as illustrated by FIG. 1A). That is, the new features (including those in FIG. 1B) herein may be added without changing the POR structure and in fact both the POR structure and new structures may be made on the same semiconductor wafer.

These improvements address the deficiencies described above.

An integrated circuit structure may therefore include the following:
a) at least a power supply rail formed in the backside of a wafer;
b) the backside power supply rail is connected to a local frontside BEOL wire through a gate.

Additional examples include the following.
1) A local frontside BEOL wire may supply power to at least one S/D epitaxial silicon area.
2) The backside power rail may connect to the gate through a gate tie-down.
3) The local frontside BEOL wire may connect to the gate through a gate via contact.
4) The N-gate may be isolated to P-gate by an N2P gate cut.
5) An N (or P) gate connected to backside power may be isolated to another N (or P) active gate that not connected to backside power by an N2N (or a P2P) gate cut.

As an overview of the exemplary embodiments, an example process flow, e.g., to form the integrated circuit structure 2, at least in part, is illustrated as the following:
1) Forming a backside gate-tie-down via at edge of the gate and filling the via with a dummy gate.
2) Forming gate patterning, S/D epi, ILD fill, gate cut.
3) Forming gate via contact to connect the dummy gate with gate-tie-down via to local M1 wire.
4) Connect some S/D which need power supplies to the local M1 wire.
5) Forming BEOL interconnect and bonding carrier wafer.
6) Flipping the wafer and removing the substrate.
7) Forming backside power rail connecting to gate-tie-down via.

As will be described further in text and corresponding figures below, an overview of an exemplary semiconductor device can include the following:

The following figures illustrate an exemplary process flow, e.g., for the previously described method and to form the integrated circuit structure 2.

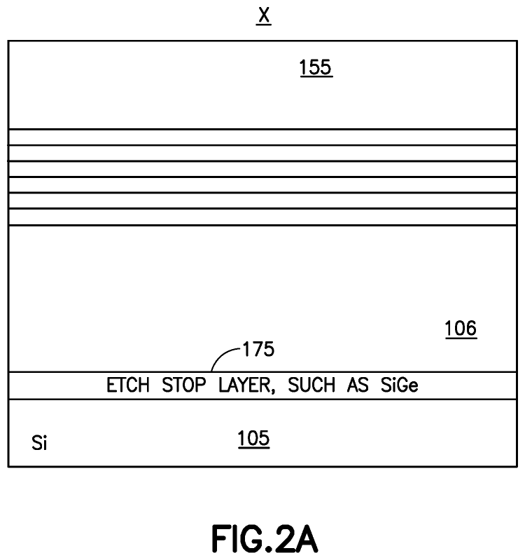

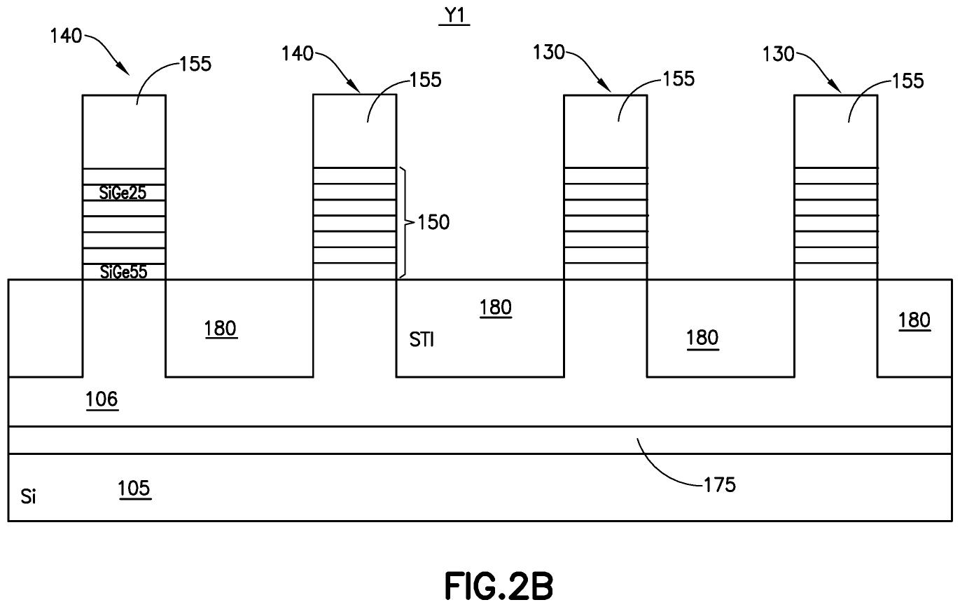

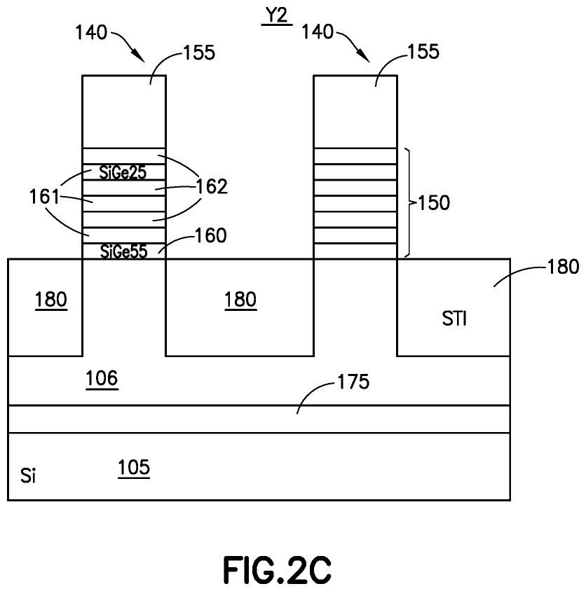

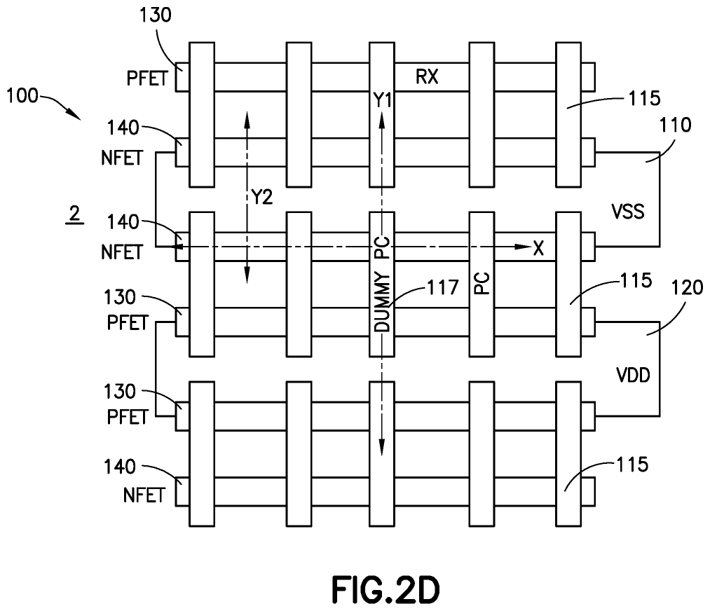

FIGS. 2A, 2B, and 2C are different cross-sectional views X, Y1, and Y2, respectively, of an integrated circuit structure 2 after NS and STI formation, while FIG. 2D illustrates a top view layout 100 of the integrated circuit structure 2 and indicates where the cross-sectional views X, Y1, and Y2 are in the layout.

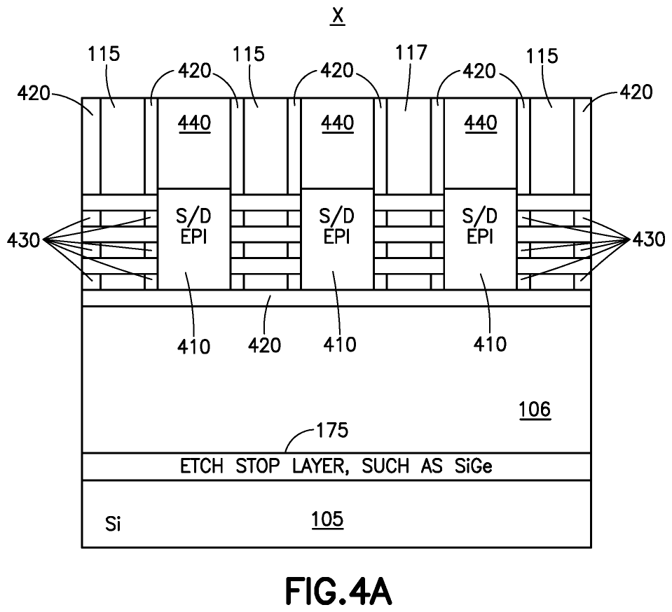

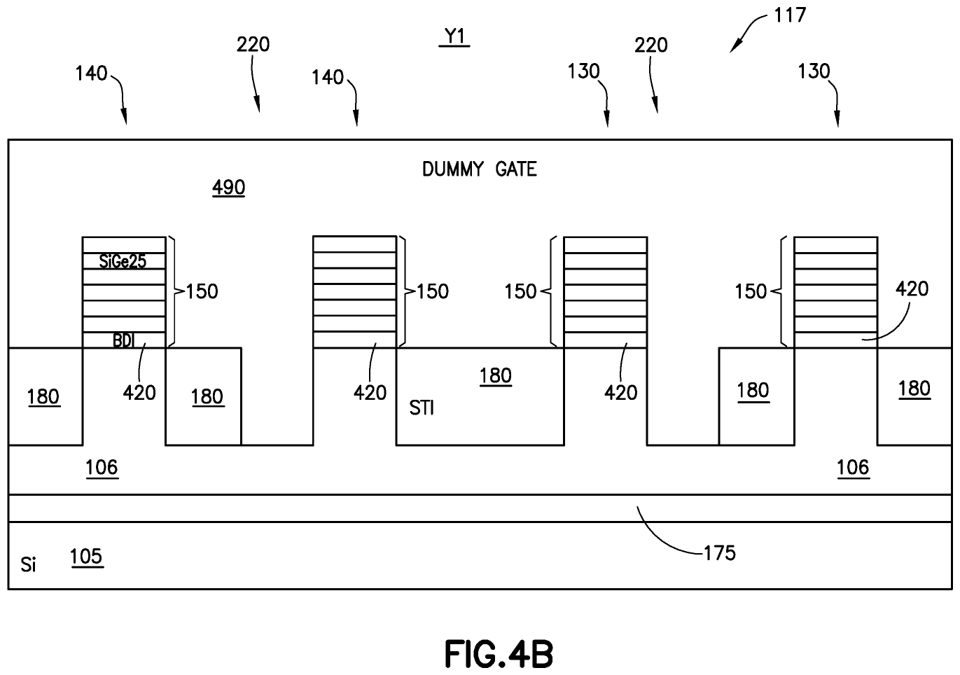

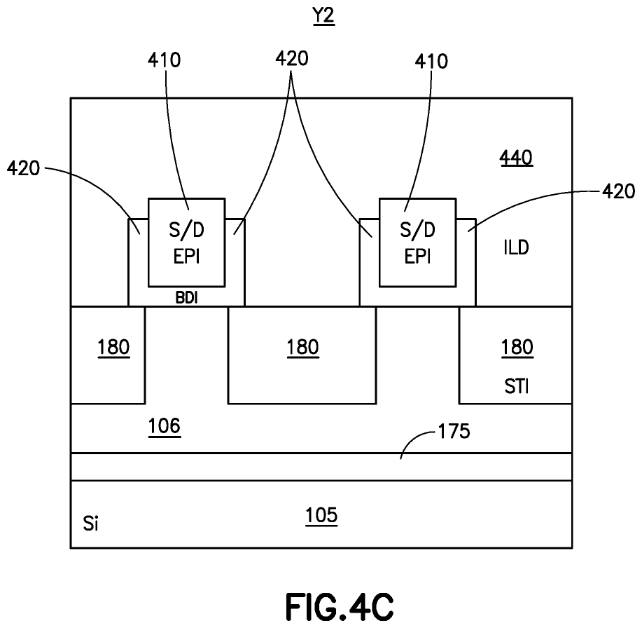

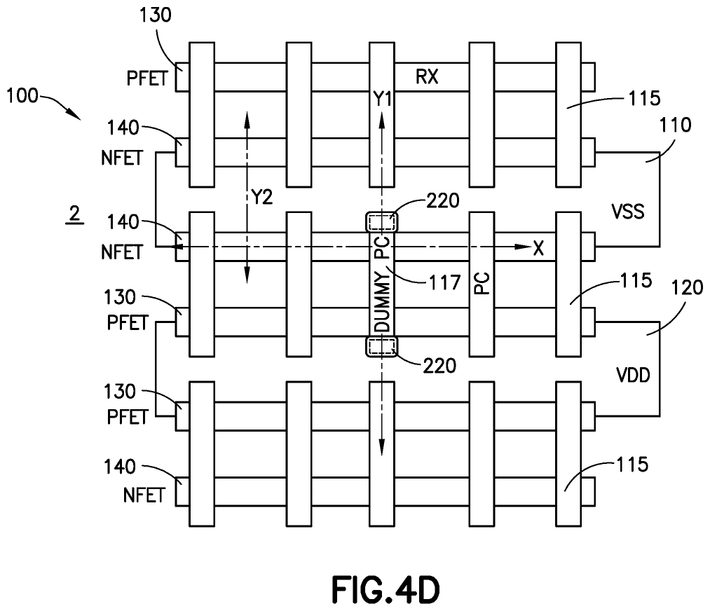

FIG. 2D shows a number of NFET regions 140 and PFET regions 130 that are doped accordingly (in a later step, see FIG. 4C), and formed in conjunction with a patterned nanosheet (referred to as an active region RX), with backside power rails of VSS region 110, and a VDD region 120. There are also three rows of gate areas 115, five each per row except that there is a dummy gate (referred to as PC) area 117. Note that in FIGS. 2A, 2B, and 2C, the PC areas 115, VSS areas 110, and VDD area 120 have not been formed yet. It is noted that the terms “area” and “region” are used herein, sometimes interchangeably. They both refer to three-dimensional formations in semiconductors.

FIGS. 2A, 2B, and 2C show a silicon (Si) substrate 105 having an etch stop layer 175 such as SiGe, and another silicon substrate 106 formed on the etch stop layer 175. A stack 150 has a layer of a first semiconductor material 160 (e.g., SiGe 55%) formed on a top surface of the substrate 106, then has alternating layers of a second semiconductor material 161 (e.g., SiGe 25%) and a third semiconductor material 162 (e.g., silicon such as monocrystalline silicon). The third semiconductor material 162 will be used in gates to form a channel. These figures show that the stack 150 has been covered with a hard mask (HM) 155, and the areas 130 and 140 for PFET and NFET areas, respectively, have been formed (e.g., via etching), as have the STI areas 180 (e.g., via deposition after the etching). The stack 150 may be considered to be a nanosheet, is it is formed via multiple thin sheets of material.

Although gate areas 115 and dummy gate area 117 are illustrated in FIG. 2D, these are not actually formed until later. That is, FIGS. 2A, 2B, and 2C do not show gates.

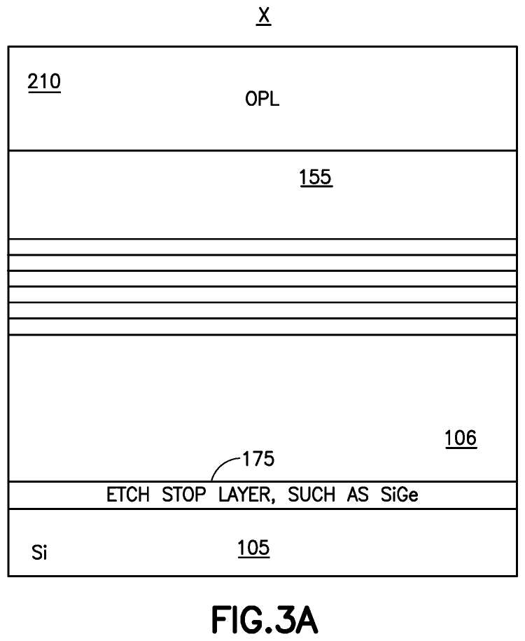

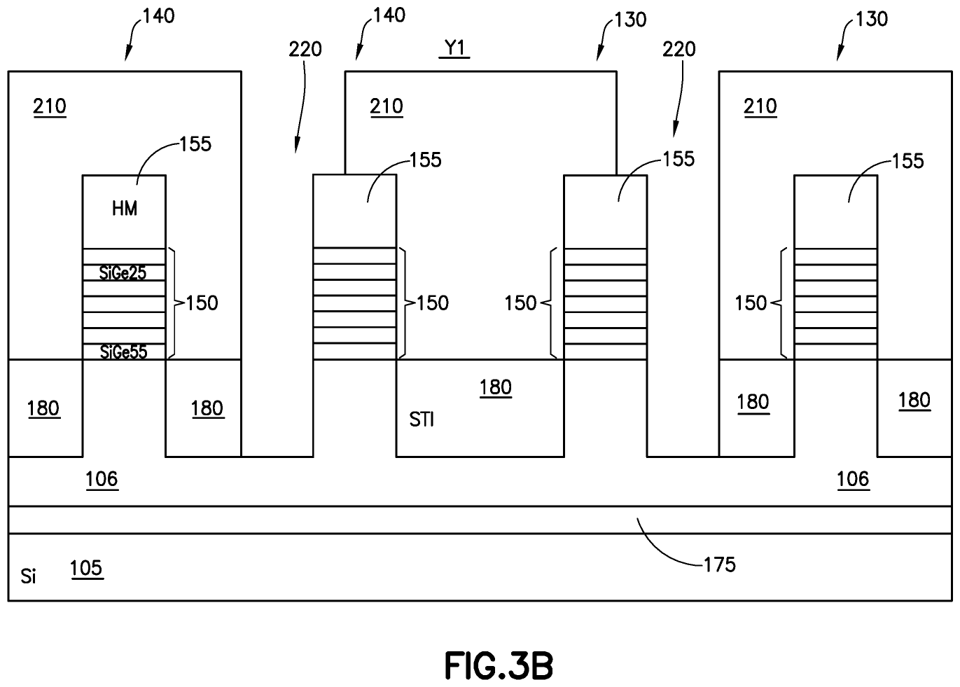

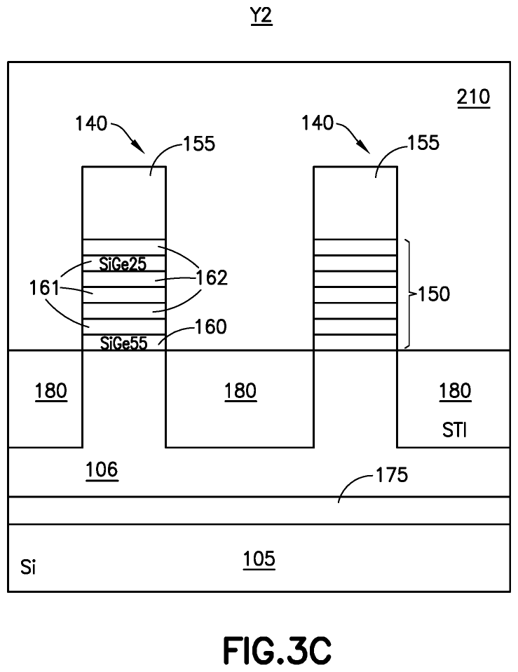

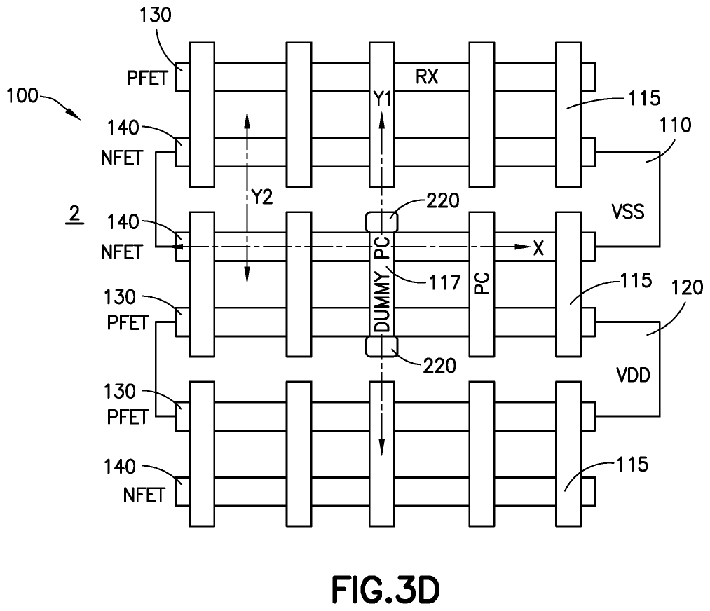

FIGS. 3A, 3B, and 3C are different cross-sectional views X, Y1, and Y2, respectively, of the integrated circuit structure after masking layer deposition (such as OPL) and patterning and gate tie-down opening formation, while FIG. 3D illustrates a top view layout of the integrated circuit structure and indicates where the cross-sectional views X, Y1, and Y2 are in the layout.

FIG. 3B, as compared to FIG. 2B, illustrates gate tie-down openings 220. FIGS. 3A, 3B, and 3C show an OPL coating 210 covering exposed surfaces of the PFET fins 130, NFET fins 140, silicon substrate 106, STI areas 180, and HM 155. OPL coating 210 can be a carbon polymer or similar. Gate tie-down openings 220 have been formed in the OPL coating 210 and STI 180 by conventional lithography and etching process in FIG. 3B to provide openings 220 to single sides of the PFET areas 130 and NFET areas 140 and through the corresponding STI areas 180 to the silicon substrate 106. The gate tie-down openings 220 will, after multiple processing steps described below, form gate tie-downs to the VSS region 110 and the VDD region 120.

FIGS. 4A, 4B, and 4C are different cross-sectional views X, Y1, and Y2, respectively, of the integrated circuit structure after OPL/HM removal, dummy gate formation, SiGe55 removal, BDI/spacer formation, nanosheet recess, inner spacer formation, S/D epi formation, ILD deposition and CMP, while FIG. 4D illustrates a top view layout of the integrated circuit structure and indicates where the cross-sectional views X, Y1, and Y2 are in the layout.

As can be seen, the OPL coating 210 and HM 155 have been removed. FIG. 4A shows gate areas 115 and the dummy gate area 117 have been formed, while FIG. 4B shows a cross-section of the dummy gate area 117. The gate areas 115 and dummy gate area 117 may be formed of material 490, such as poly-Si or amorphous Si (please note that there may be a thin layer of SiO₂ between the material 490 and nanosheet stack 150, although this is not shown and is deposited and appropriately modified using known techniques). The references 220 indicate where the gate tie-down openings used to be. The SiGe 55% layer 160 in the stack 150 has been removed and the BDI (bottom dielectric isolation) layer 420 has taken its place, see FIG. 4B. FIG. 4A also shows the BDI layer 420 underlying the channel regions and S/D regions 410, and ILD layer 440 covering the S/D epi (epitaxial) regions 410. FIG. 4C illustrates that the previous nanosheet material in the stack 150 has been removed, how the BDI layer 420 surrounds three layers of the S/D epi (epitaxy) regions 410, and the S/D epi regions 410 have been formed. ILD layer 440 has been deposited. Inner spacers 430 have been formed e.g., from an insulating material, after an etch back of SiGe layers 161, then deposition of material 420 into these areas.

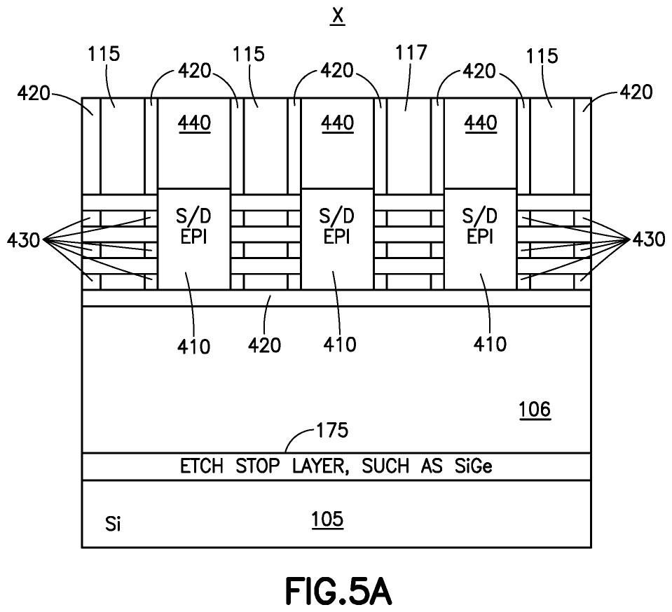

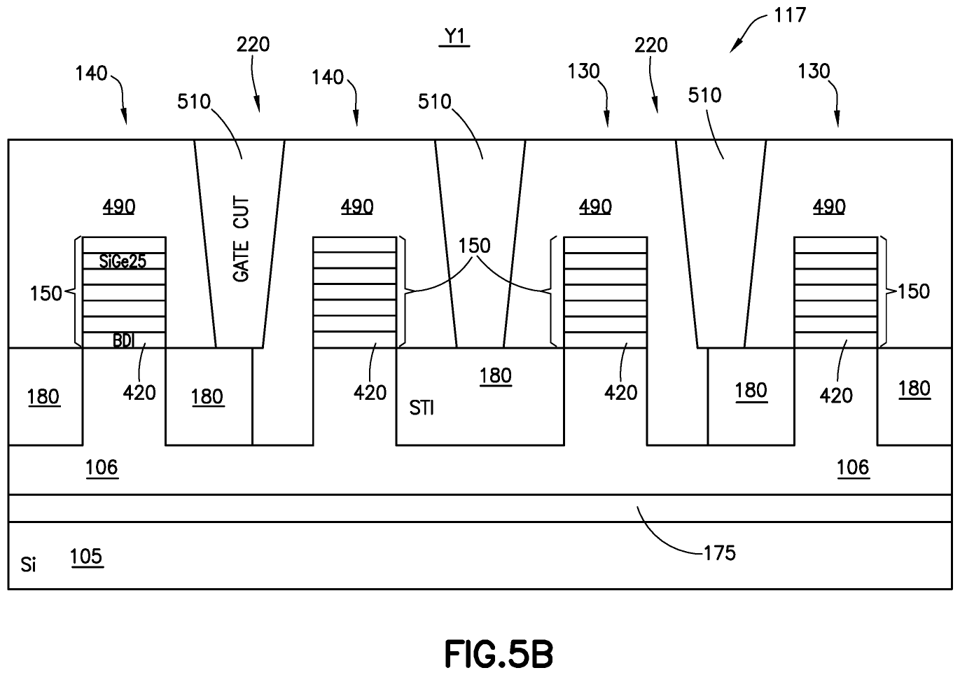

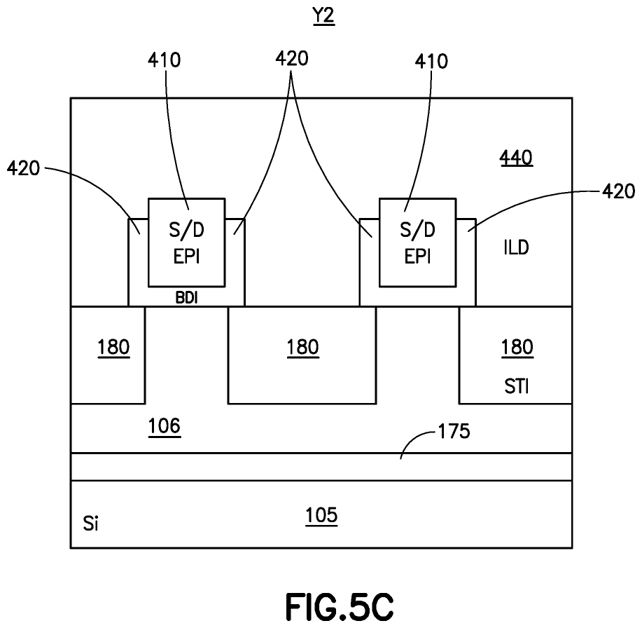

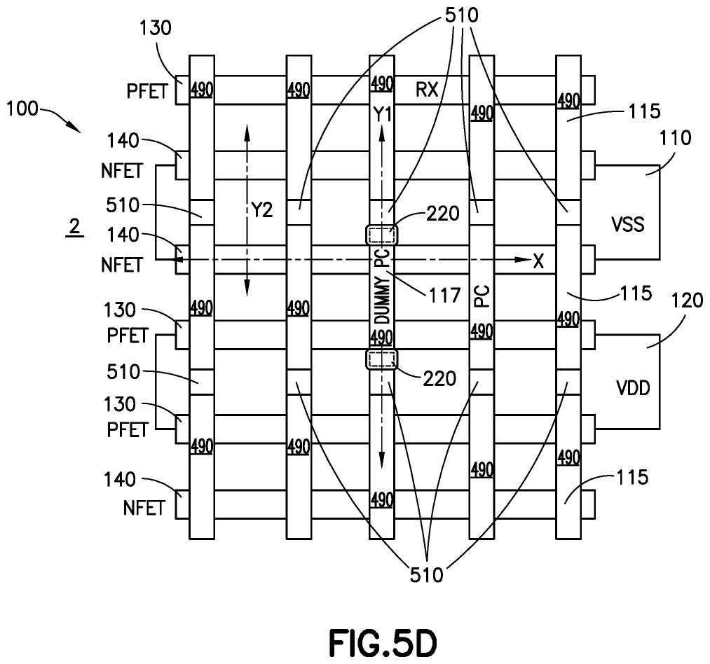

FIGS. 5A, 5B, and 5C are different cross-sectional views X, Y1, and Y2, respectively, of the integrated circuit structure after gate cut formation, while FIG. 5D illustrates a top view layout of the integrated circuit structure and indicates where the cross-sectional views X, Y1, and Y2 are in the layout. FIGS. 5B and 5D show the gate cuts 510 that have been formed and filled with dielectric material such as SiO₂, SiN, SiBCN, SiOCN, SiOC, and the like.

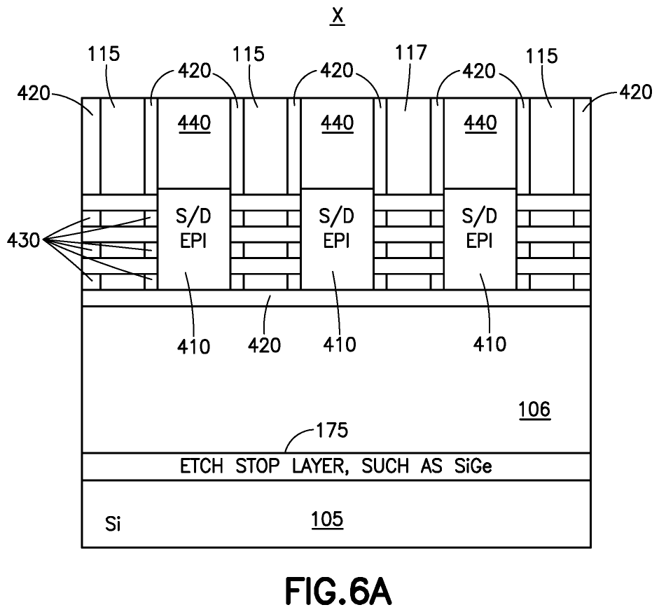

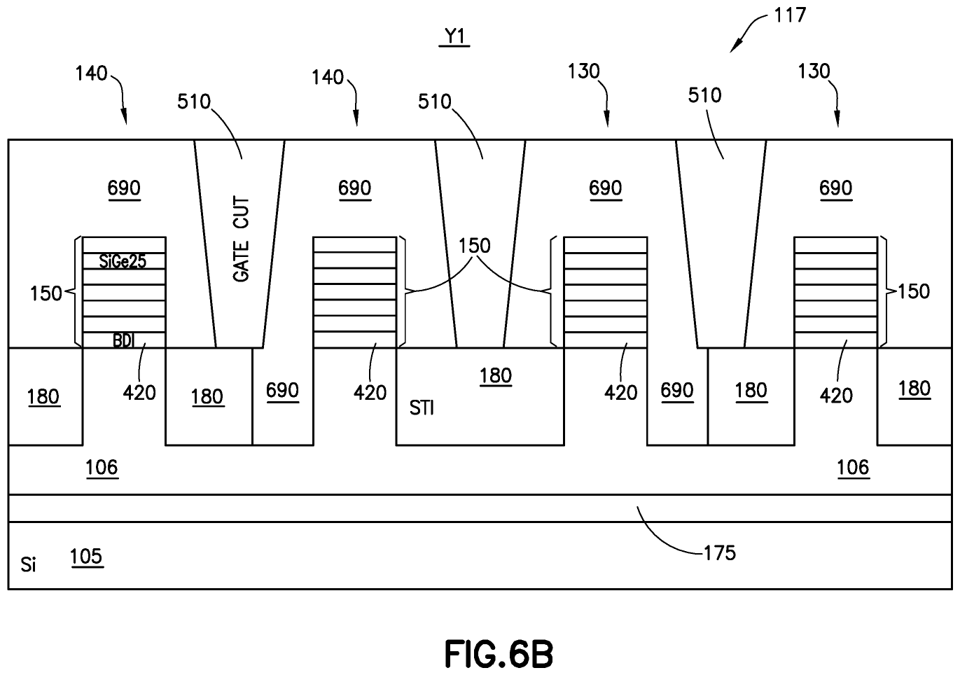

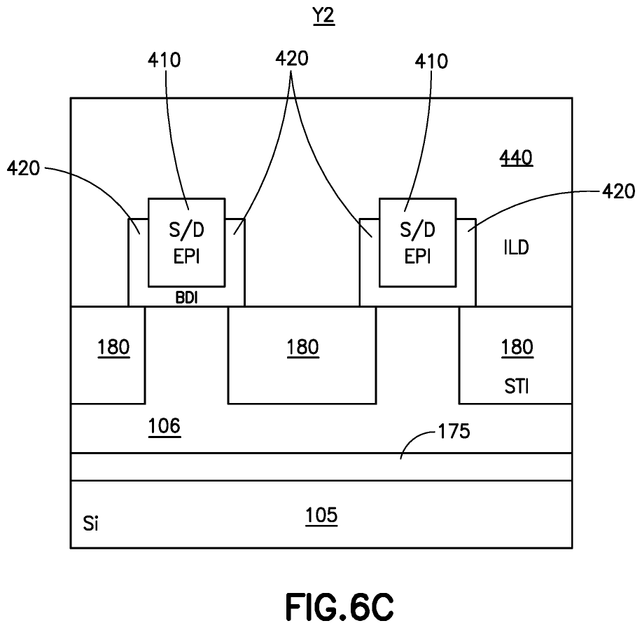

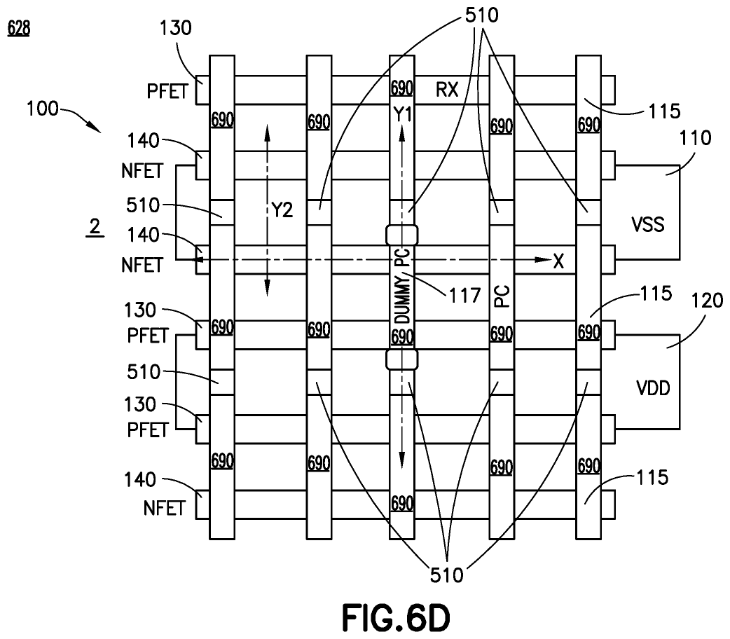

FIGS. 6A, 6B, and 6C are different cross-sectional views X, Y1, and Y2, respectively, of the integrated circuit structure after dummy gate removal, SiGe release, and replacement high k metal gate formation, while FIG. 6D illustrates a top view layout of the integrated circuit structure and indicates where the cross-sectional views X, Y1, and Y2 are in the layout. The dummy gate area 117 is still illustrated but material 490 in this area has been removed. There has been release of the SiGe 25% layers 161, so that second semiconductor material layers 162 are still remaining and used for the channel regions. The gate areas 115 and 117 have had their material replaced from material 490 to a high-k metal gate layer 690. The high-k metal gate layer 690 may include a gate dielectric layer, such as HfO₂, HfSiOₓ, HfAlOₓ, HfLaOₓ, ZrOₓ, etc, and workfunction metals, such as TiN, TiC, TiAl, TiAlC, and the like, and optional conductive metals, such as W, or Co, or Al, which can be deposited by conformal deposition, as is known.

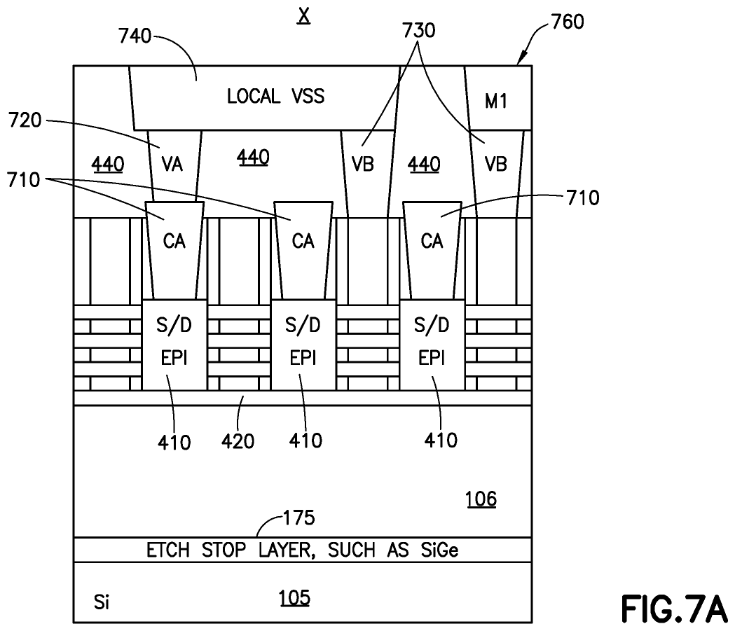

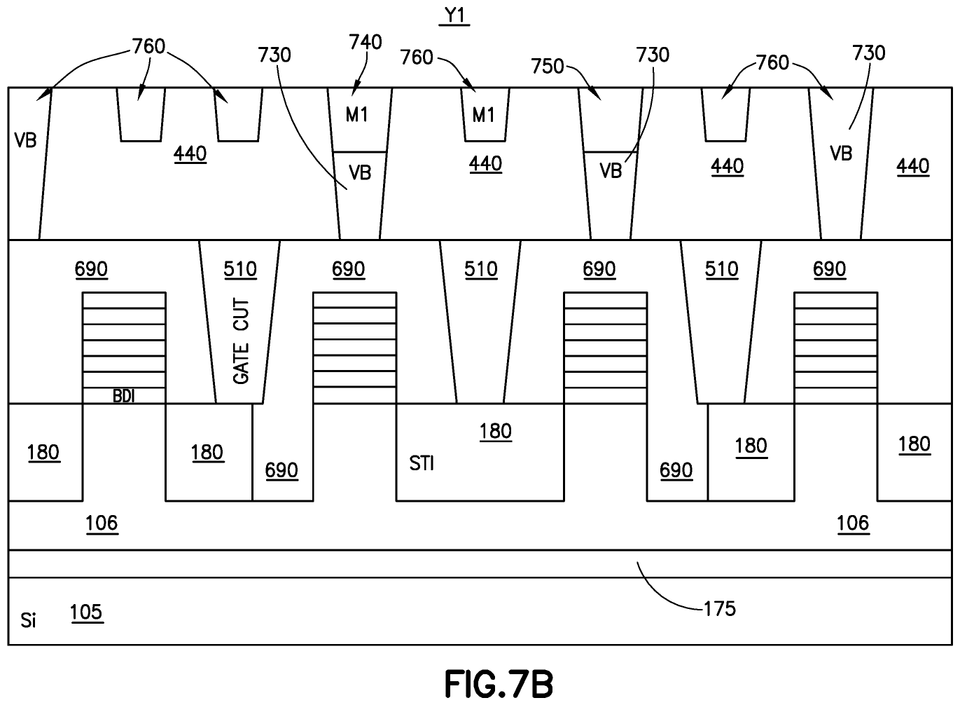

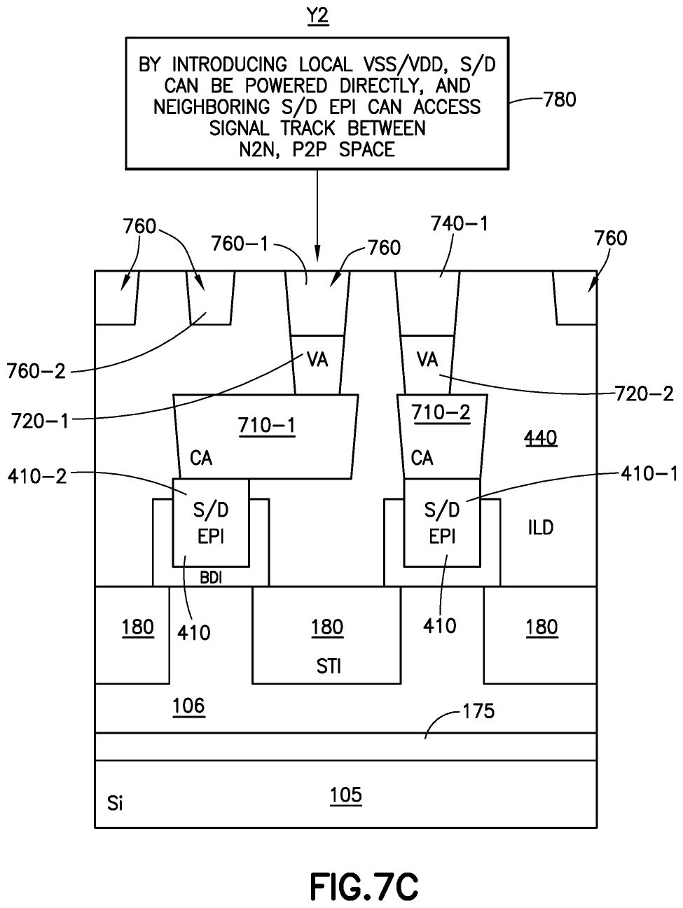

FIGS. 7A through 12C use the layout 100 and cross-sections X, Y1, and Y2, as illustrated in FIG. 6D.

FIGS. 7A, 7B, and 7C are different cross-sectional views X, Y1, and Y2, respectively, of the integrated circuit structure after MOL processing, and lower BEOL formation with VDD/VSS local supply from a dummy gate tie-down. FIG. 7A illustrates that, as part of the MOL processing, contacts 710 (CA) have been formed, above the S/D epi regions 410, in ILD layers 440 to the S/D epitaxial regions 410. Additionally, an ILD layer 440 has been formed (e.g., as part of lower BEOL formation), and the vias A 720 and B 730 have been formed in FIGS. 7A, 7B, and 7C. As part of the lower BEOL formation, the local V_{SS} 740 (to VA 720 and VB 730) has been added, and signal track 760 (using M1 metal layer) has been added to VB 730 in FIG. 7A. Multiple signal tracks 760 are shown in FIG. 7B, and a local V_{SS} 740 is connected to a VB 730, along with a local VDD 750, shown connected to a VB 730. Some of the signal tracks 760 are connected to vias such as VB 730 in FIG. 7B. FIG. 7C also shows two contacts CA 710 to individual ones of the S/D epitaxial regions 410, and vias VA 720 to the contacts CA 710 and then to a corresponding signal track 760 or to a local V_{SS} 740.

The local V_{SS} 740 or VDD 750 is part of BEOL (in M1), and it supplies ground or power, respectively, for only few transistors nearby, therefore it is referred to as “local” (as contrasted with “global”). A more specific definition is the following: a local V_{SS}/VDD is a segment of M1 wire, which only supplies power for transistors within 10 contacted poly pitch (CPP).

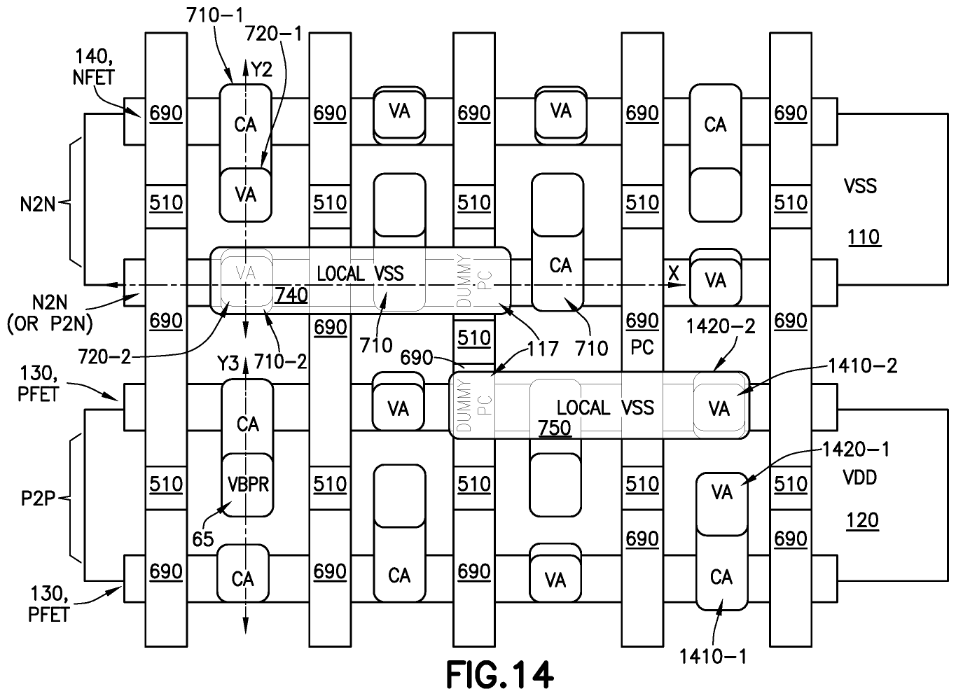

As indicated by reference 780, by introducing local V_{SS} 740 and/or local VDD 750, the S/D can be powered directly, and neighboring S/D epitaxial regions can access a signal track within N2N, P2P regions. That is, the local V_{SS} 740-1 is introduced, so the S/D epitaxial region 410-1 can be powered directly (e.g., instead of having to connect through a VBPR to the backside V_{SS} as illustrated in FIG. 1A) using the via VA 720-1, which is coupled to the local V_{SS} 740-1. Further, the neighbor S/D epitaxial region 410-2 can access a signal track 760-1 between two NFET regions (see FIG. 6D and the NFET areas 140, or FIG. 14 and the N2N). Moreover, the CA 710-1 above the S/D epi 410-2 allows this epi 410-2 to connect either to signal track 760-1 (using via VA 720-2) or signal track 760-2 (using a via not shown).

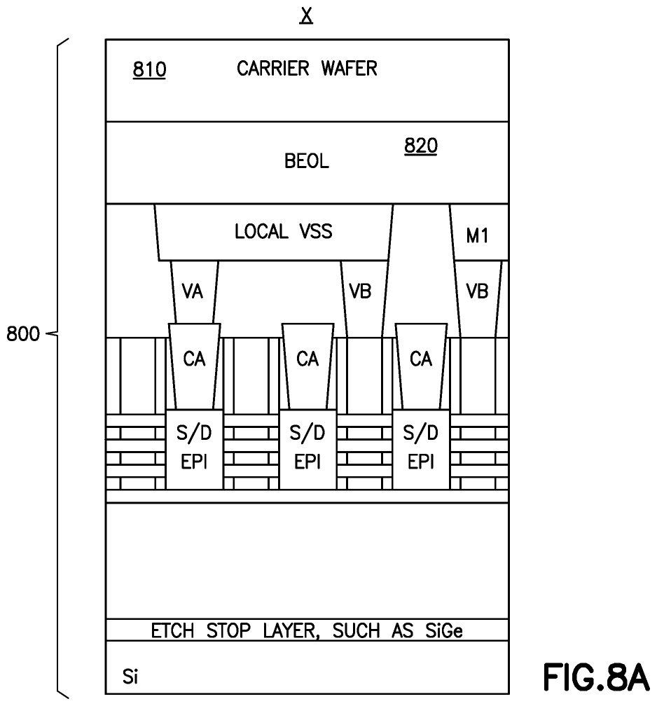

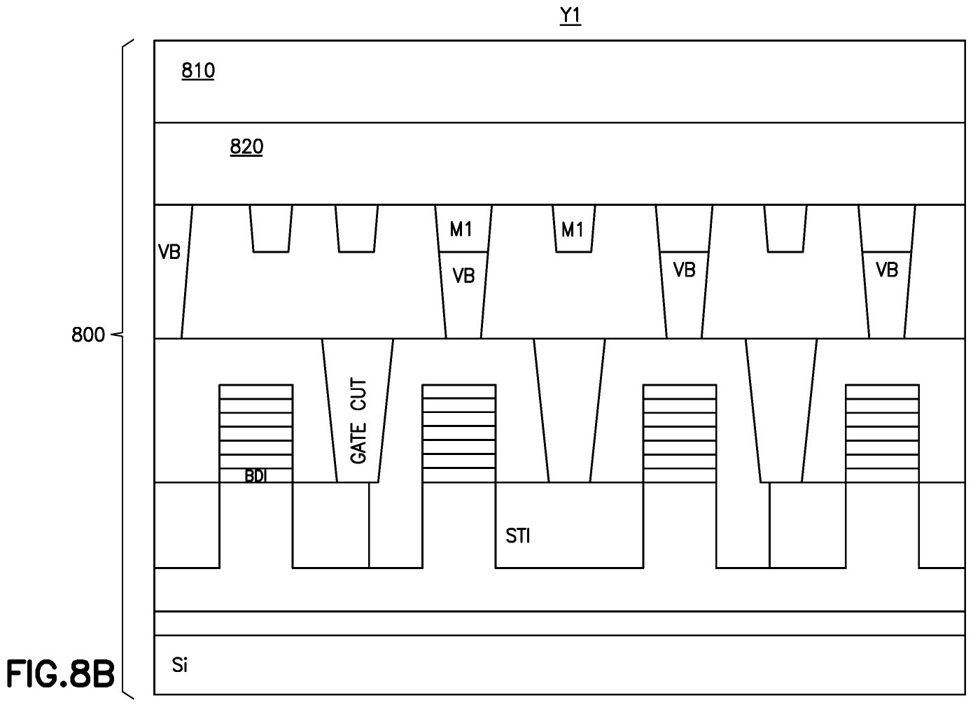

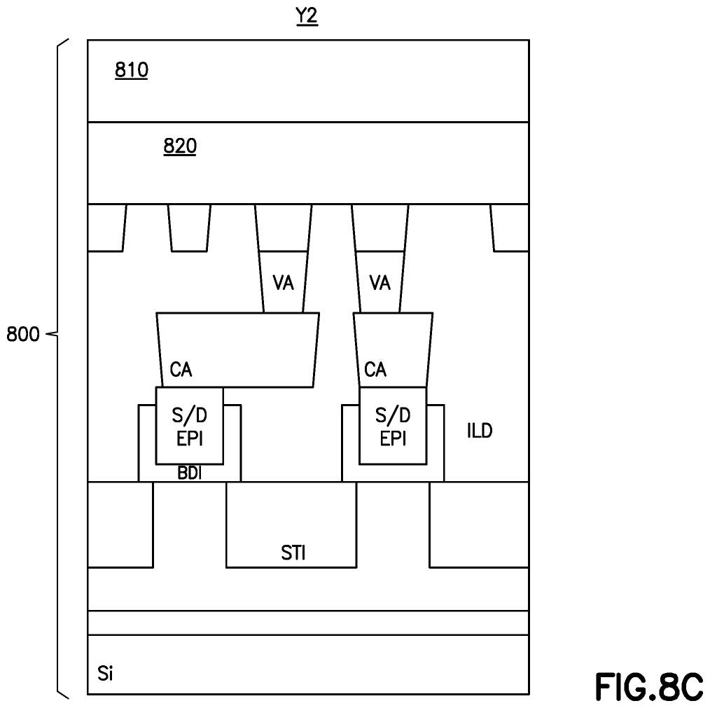

FIGS. 8A, 8B, and 8C are different cross-sectional views X, Y1, and Y2, respectively, of the integrated circuit structure after forming more BEOL levels and bonding a carrier wafer. FIGS. 8A, 8B, and 8C are the same as respective FIGS. 7A, 7B, and 7C, but for the additions of a BEOL layer 820 and a carrier wafer 810. The carrier wafer 810 has been bonded to the BEOL layer 820. Reference 800 indicates the semiconductor wafer that is being processed.

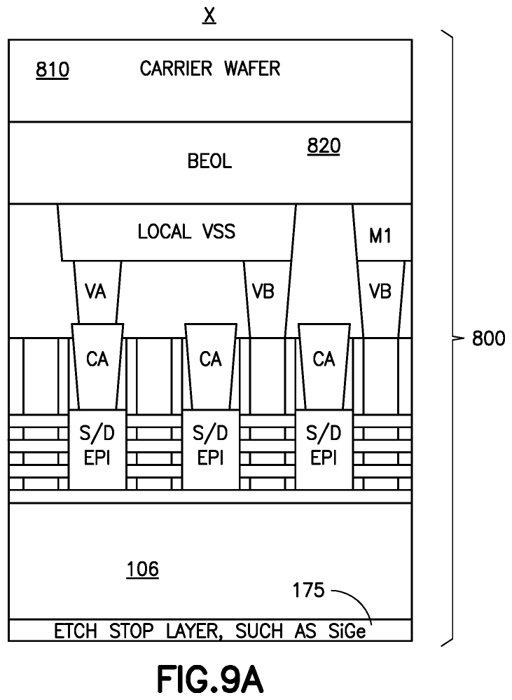

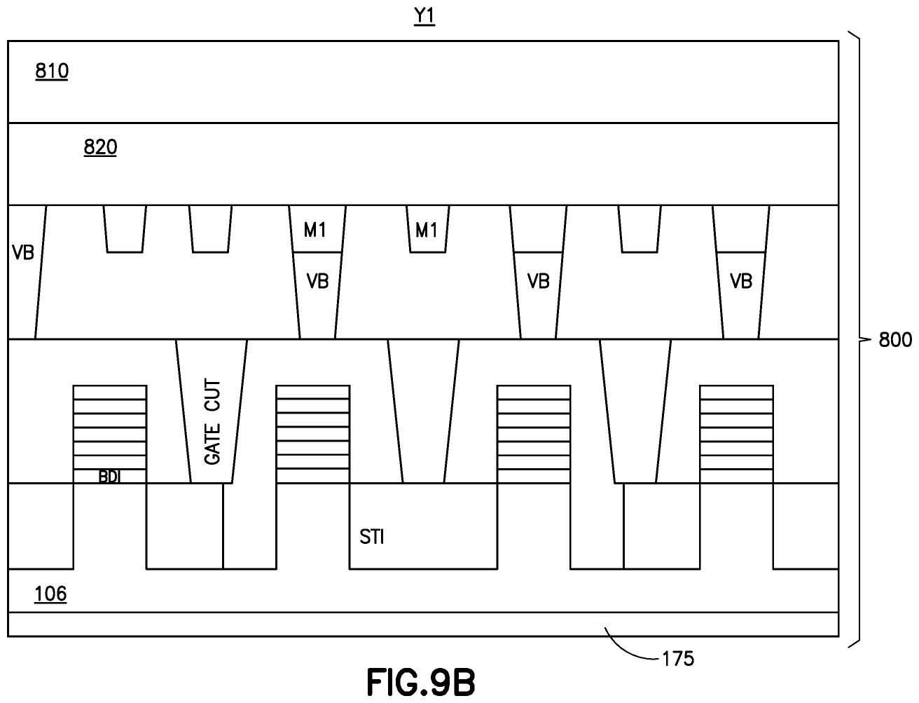

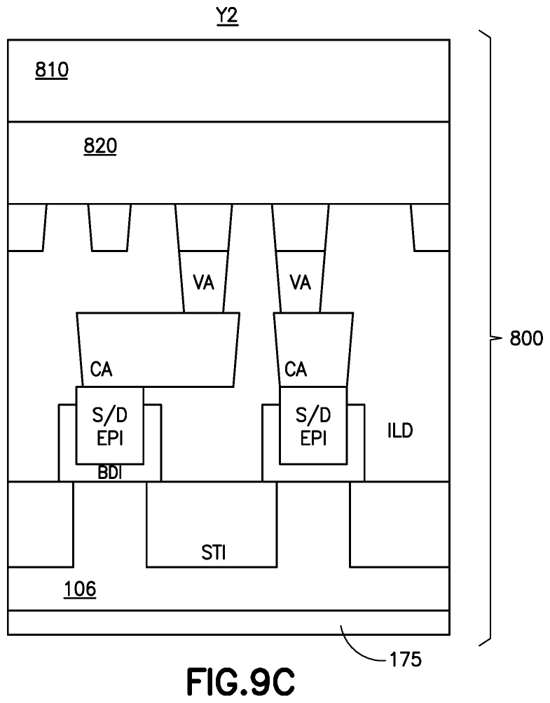

FIGS. 9A, 9B, and 9C are different cross-sectional views X, Y1, and Y2, respectively, of the integrated circuit structure after a wafer flip, substrate removal, and stopping on etch stop layer. FIGS. 9A, 9B, and 9C are the same as respective FIGS. 8A, 8B, and 8C, but the wafer 800 has been flipped for processing, the substrate 105 has been removed via etching to the etch stop layer 175.

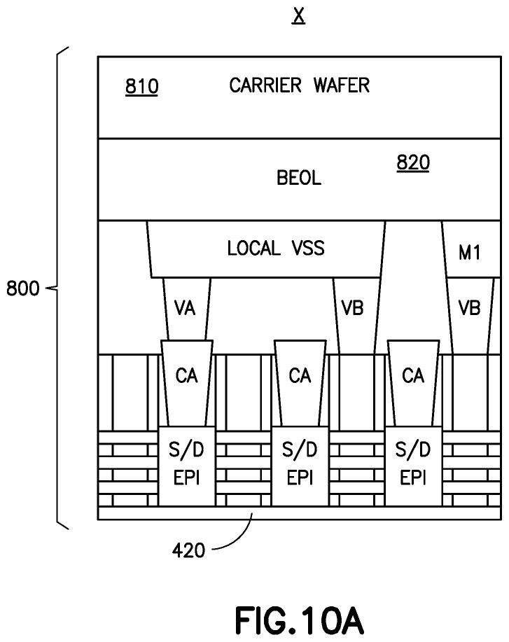

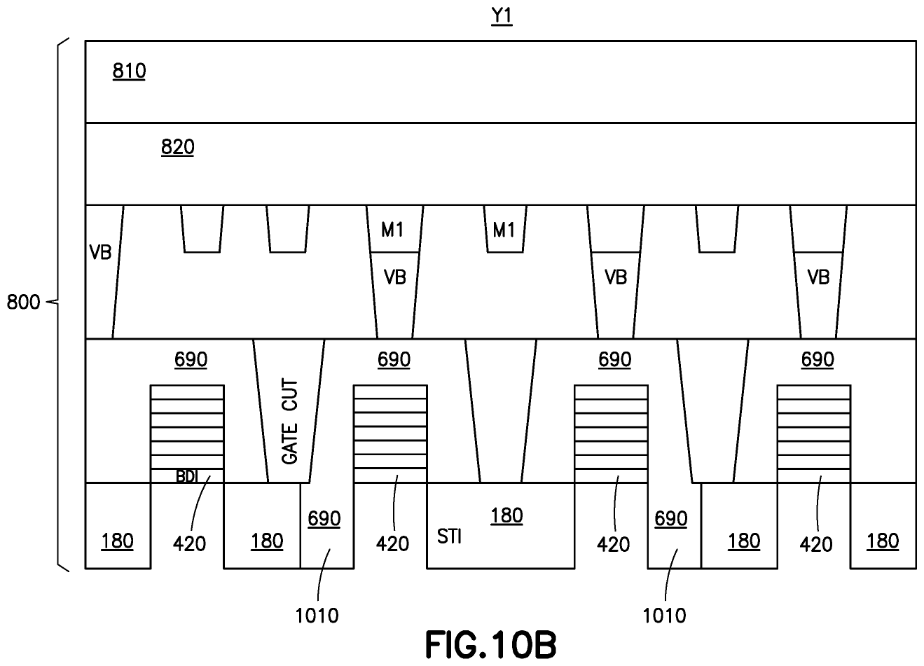

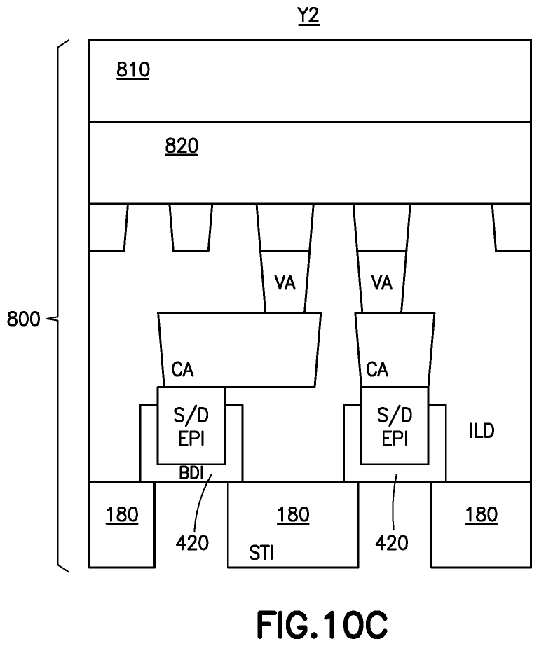

FIGS. 10A, 10B, and 10C are different cross-sectional views X, Y1, and Y2, respectively, of the integrated circuit structure after etch stop layer removal and remaining Si removal. These figures illustrate that the etch stop layer 175 has been removed as has silicon substrate 106, back to the STI layer 180 and the BDI layer 420. The regions 1010 of gate metal layer 690 are to be the gate tie-downs and were formed via processing that began at FIG. 3B with formation of gate tie-down openings 220.

FIGS. 11A, 11B, and 11C are different cross-sectional views X, Y1, and Y2, respectively, of the integrated circuit structure after backside ILD formation, and backside power rail formation. The BILD layer 1110 has been formed over exposed areas of the STI areas 180 and BDI layer 420. The BILD layer 1110 has been patterned (see FIGS. 11B and 11C) and conductive material deposition to form V_{SS} region 110, a ground rail 1160-1, and VDD region 120, a power rail 1160-2. The regions 1010 of gate metal layer 690 are now gate tie-down 1010-1 and 1010-2. Note that gate tie-downs 1010-1 and 1010-2 may also be considered to be vias and can be formed using techniques for forming such vias.

Furthermore, the ground rail 1160-1 and power rail 1160-2 can be generalized to a power supply rail 1160, as both V_{SS} and VDD are power supplies. That is, V_{SS} is the power supply for NFET, and VDD is the power supply for PFET.

There are two dummy gates 1130 illustrated, an N-dummy gate 1130-1 and a P-dummy gate 1130-2. The N-dummy gate 1130-1 uses an NFET area 140, and the P-dummy gate 1130-2 uses a PFET area 130. The N-dummy gate 1130-1 and the P-dummy gate 1130-2 are isolated from each other at least by the gate cut 510-1, though other techniques could be used for isolation. The N-dummy gate 1130-1 can be isolated from the N-active gate 1140-1 (having a gate that uses S/D regions of the corresponding NFET area 140 to form a corresponding NFET) by the gate cut 510-2. Note that the gate 1140-1 is not active in this example (e.g., there is no via VB connected to the channel region), but the gate could be active in other examples. The P-dummy gate 1130-2 can be isolated from the P-active gate 1140-2 (having a channel formed within the gate region and using the corresponding PFET area 130 to form a corresponding PFET) by the gate cut 510-3.

A gate-tie-down means the device is turned off by its gate. For an NFET, it needs to be turned off by adding a V_{SS} power supply to the gate. This is the way N-dummy gate 1130-1 is constructed, e.g., using the ground rail 1160-1. For a PFET, it needs to be turned off by adding a VDD power supply to the gate to turn off. This is the way P-dummy gate 1130-2 is constructed, e.g., using power rail 1160-2.

As illustrated, ground rail 1160-1 and its corresponding gate 1130-1 and the power rail 1160-2 and its corresponding gate 1130-2 are adjacent. It is noted that there could be two adjacent ground rails 1160-1 and corresponding gates 1130-1, or two adjacent power rails 1160-1 and corresponding gates 1130-2, if desired, although the dummy gate 117 would have to span two NFET regions or two PFET regions, respectively, instead of spanning an NFET region and a PFET region as in the above examples.

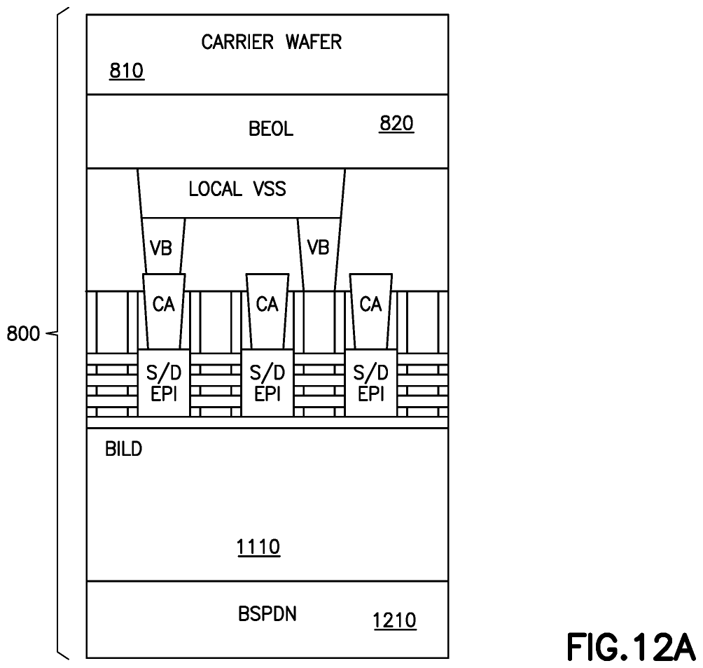

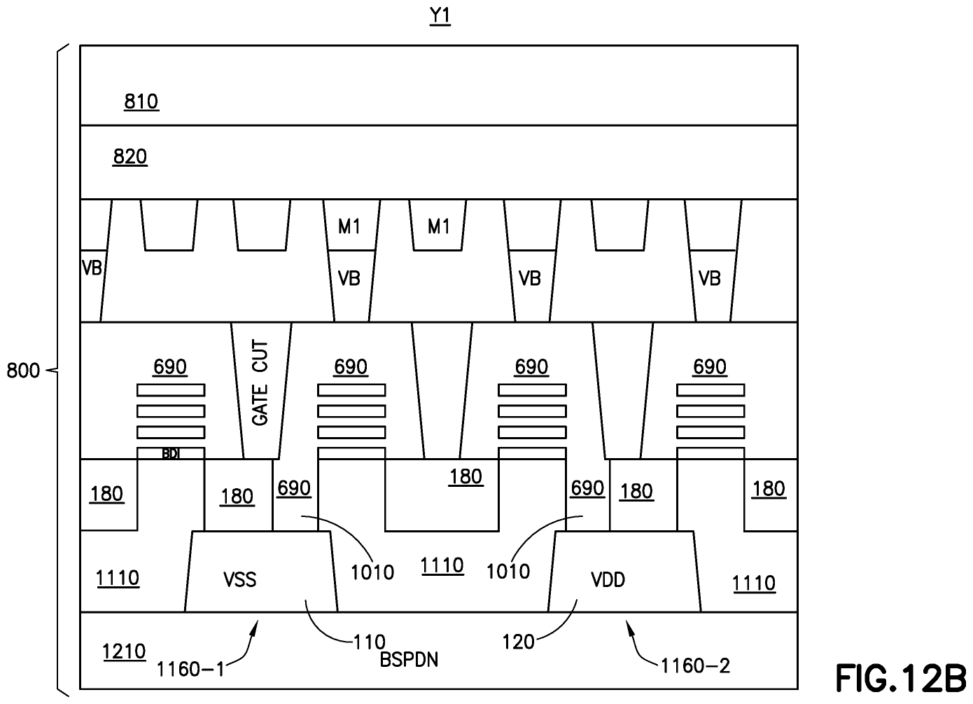

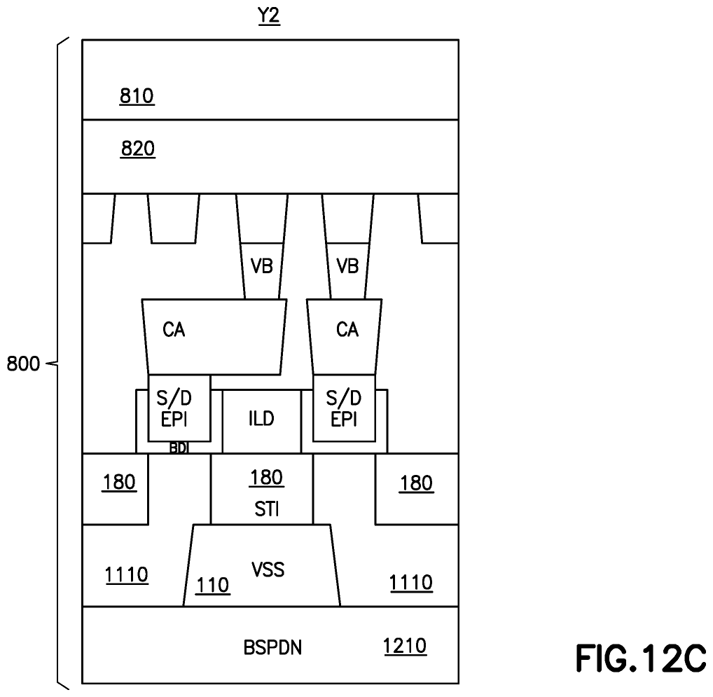

FIGS. 12A, 12B, and 12C are different cross-sectional views X, Y1, and Y2, respectively, of the integrated circuit structure after forming a backside power distribution network layer. With respect to FIGS. 11A, 11B, and 11C, the BSPDN layer 1210 has been formed on the exposed surfaces of the BILD layer 1110, the V_{SS} region 110, and the VDD region 120.

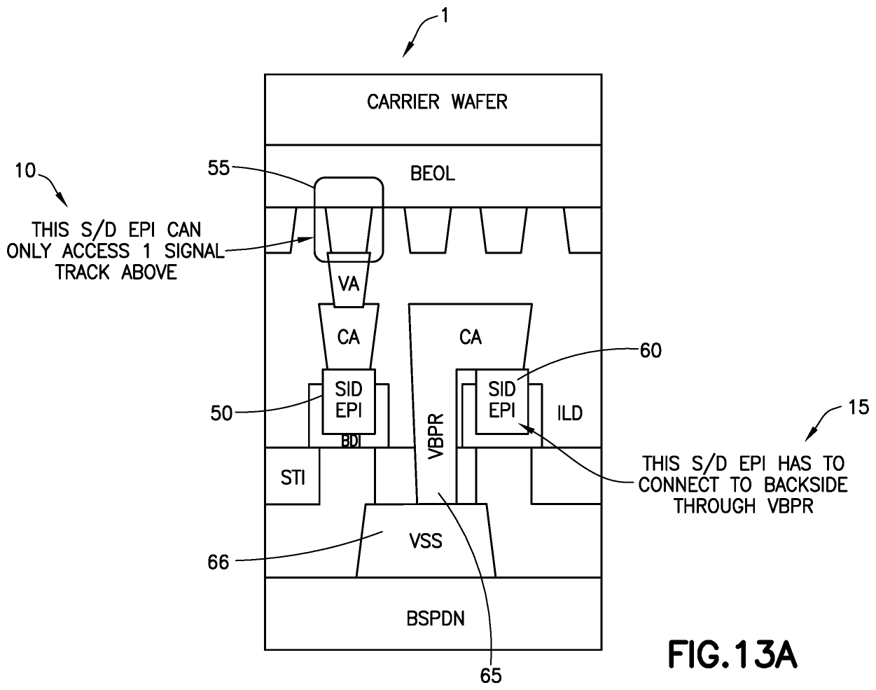

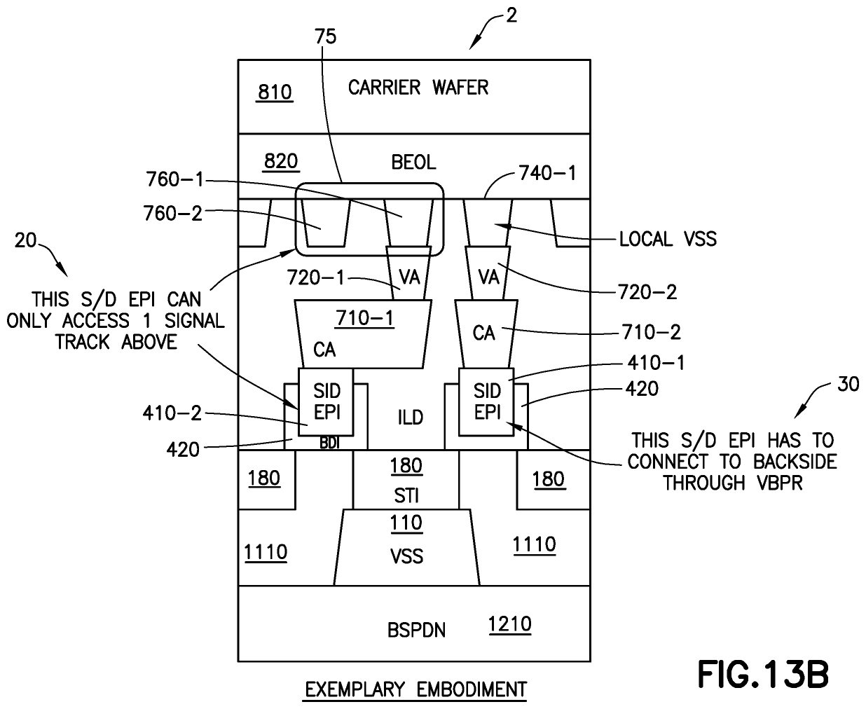

FIG. 13A is an example of a conventional POR integrated circuit structure taken from cross-sectional view Y3 in FIG. 14, while FIG. 13B is an example of an integrated circuit structure of an exemplary embodiment herein. FIG. 13A is the same as FIG. 1A but is repeated for ease of reference. FIG. 13A is an example of a conventional POR integrated circuit structure 1. As illustrated by reference 10, the S/D epi (epitaxial silicon area) 50 has access to only one (1) signal track 55 above (e.g., near the BEOL layer). As indicated by reference 60, the S/D epi area 60 has to connect to the backside through the VBPR 65, which is connected to the V_{SS} area 66. It is noted that the techniques herein are fully compatible with the POR process, as illustrated by FIGS. 13A, 13B, and 14. That is, the new features herein may be added without changing the POR structure.

FIG. 13B is FIG. 1B, but has been updated with the reference numbers used in previous figures starting with FIG. 2A. This is taken from cross-sectional view Y2 as shown in FIG. 14. As indicated in FIG. 13B, an integrated circuit structure 2 is illustrated of an exemplary embodiment herein. As indicated by reference 20, the S/D epi 410-2 can freely access the two signal tracks 760-1 and 760-2, as indicated by reference 75. In this example, signal track 760-1 is accessible using the via VA 720-1, but signal track 760-2 is also easily accessible instead. Signal track 760-1 is within an N2N region (see FIG. 14 too) in this example, but could also be in a P2P region (see FIG. 14), which provides further opportunities for signal routing. As indicated by reference 30, the S/D epi 410-1 is powered by local V_{SS} 740-1 from above (through via VA 720-2). These improvements address the deficiencies described above with respect to FIG. 13A.

Turning to FIG. 14, this figure provides a detailed top-down layout on S/D contact, VBPR and VAs. The cross-sections X, Y1, and Y2, as shown in the previous figures are indicated in FIG. 14. Cross-section Y3 is also shown, as used in FIG. 13A. The NFET regions The PC regions, which comprise gate metal layers 690, are shown. The V_{SS} region 110, VDD region 120, PFET regions 130, NFET regions 140 are shown. Gate cuts 510 are illustrated. The dummy PC area 117 is also illustrated. The local V_{SS} region 740 is above the via VA 720-2, which contacts and is above the CA 710-2, and the via VA 720-1 is above the contact CA 710-1 and both are in the N2N region (the VA 720-1 is fully in the N2N region and the CA 710-1 is partly in this region). See also, e.g., FIG. 7C, which shows the Y2 cross-section.

The local VDD region 750 is illustrated in FIG. 14 and the three gate cuts 510 along the cross-section Y1 can also be seen in FIG. 7B, as can the local VDD (connected to an underlying via VB 730, not shown in FIG. 14). The local VDD region 750 is above the via VA 1420-2 (similar to 720-2), which contacts and is above the CA 1410-2 (similar to 710-2), and the via VA 1420-1 (similar to 720-1) is above the contact CA 1410-1 (similar to 710-1), and both are in the P2P region (the VA 1420-1 is fully in the P2P region and the CA 1410-1 is partly in this region).

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The following abbreviations that may be found in the specification and/or the drawing figures are defined as follows:
BDI bottom dielectric isolation
BEOL back end of line
BILD backside interlayer dielectric
BSPDN backside power distribution network
CA source/drain contact
CPP contacted poly pitch
epi epitaxial silicon (area)
HM hard mask
ILD interlayer dielectric
M1 a first metal layer
MOL middle of line
N2N n-type (NFET) to n-type (NFET) semiconductor areas
N2P n-type to p-type semiconductor areas
NFET n-type field effect transistor
NS nanosheet
OPL optical planarization layer
P2P p-type (PFET) to p-type (PFET) semiconductor areas
PC a gate area
PFET p-type field effect transistor
POR process of record
RX active region
S/D source/drain
S/D epi source/drain epitaxy
STI shallow trench isolation
VBPR via-to-backside power rail

What is claimed is:

1. An integrated circuit structure, comprising:
a power supply rail formed in a backside of a semiconductor wafer; and
a frontside back end of line (BEOL) wire layer connected to the power supply rail through a gate, wherein the gate is of a type to be powered off by a power supply coupled through the gate from the power supply rail to the first frontside BEOL wire layer.

2. The integrated circuit structure according to claim 1, further comprising a frontside BEOL wire that is connected to one or more source/drain epitaxy silicon areas of corresponding transistors.

3. The integrated circuit structure according to claim 2, wherein the frontside BEOL wire is connected to the one or more source/drain epitaxy silicon areas of corresponding transistors using corresponding one or more vias.

4. The integrated circuit structure according to claim 2, wherein the frontside BEOL wire layer is connected to the frontside BEOL wire.

5. The integrated circuit structure according to claim 1, wherein the power rail connects to the gate through a gate-tie-down via that electrically connects the power supply rail to a portion of the gate.

6. The integrated circuit structure according to claim 1, wherein the frontside BEOL wire layer connects to the gate through a gate via contact.

7. The integrated circuit structure according to claim 1, wherein:
the gate is a first gate and the power supply rail is a first power supply rail;
the integrated circuit structure further comprises:
a second power supply rail formed in the backside of the semiconductor wafer; and
another frontside BEOL wire layer connected to the second power supply rail through a second gate, wherein the second gate is of a type to be powered off by a power supply coupled through the second gate from the second power supply rail to the other frontside BEOL wire layer.

8. The integrated circuit structure according to claim 7, wherein:
the first gate is an n-type gate and the power supply for the first gate is ground; and
the second gate is a p-type gate, and the power supply for the first gate is power.

9. The integrated circuit structure according to claim 7, wherein the first and second gates are formed adjacent to each other and isolated at least by a gate cut formed between the adjacent first and second gates.

10. The integrated circuit structure according to claim 9, wherein the first gate is formed at least in part in a first doped region of a first type, the second gate is formed at least in part in a second doped region of a second type, and the gate cut is formed in a region between the first and second doped regions.

11. The integrated circuit structure according to claim 1, wherein:
the integrated circuit structure further comprises a source/drain contact contacting a corresponding source/drain region withing a doped region and extending beyond the source/drain region to provide access to one of a signal track that is in a region between the doped region and another doped region of the same type and a signal track that is within the doped region.

12. The integrated circuit structure according to claim 1, wherein a gate connected to a power supply rail formed in the backside is isolated by a gate cut to an adjacent active gate that is not connected to the power supply rail formed in the backside.

13. The integrated circuit structure according to claim 12, wherein:
the gate connected to the power supply rail formed in the backside and the adjacent active gate are of the same type and are formed at least in part in individual ones of two doped regions having this same type; and
the gate cut between the gate connected to the power supply rail formed in the backside and the adjacent active gate is formed in a region between the two doped regions of the same type.

14. A method of forming an integrated circuit structure, comprising:
forming a power supply rail in a backside of a semiconductor wafer;
forming a gate in the semiconductor wafer; and
forming a frontside back end of line (BEOL) wire layer connected to the power supply rail through the gate, wherein the gate is of a type to be powered off by a power supply coupled through the gate from the power supply rail to the first frontside BEOL wire layer.

15. The method according to claim 14, wherein:
forming the gate in the semiconductor wafer further comprises forming multiple gates on a substrate of the semiconductor wafer, wherein forming the multiple gates comprises:
performing gate patterning to pattern multiple gates on a substrate, of which the gate is one;
performing source/drain epitaxy to form source/drain regions for the multiple gates;
performing interlayer dielectric deposition to cover at least the source/drain regions and at least partially isolating the multiple gates; and
forming a frontside back end of line (BEOL) wire layer comprises forming BEOL interconnects and bonding a carrier wafer to the substrate on which the multiple gates have been formed.

16. The method according to claim 15, wherein:
forming the gate in the semiconductor wafer further comprises forming a backside gate-tie-down via at an edge of the gate and filling the backside gate-tie-down via with conductive material at a same time conductive material forming the gate is formed;
the method further comprises forming a gate via contact to connect the gate having the gate-tie-down via to the frontside back end of line (BEOL) wire layer; and
the method further comprises further comprises connecting the power supply rail to the gate-tie-down via.

17. The method according to claim 15, further comprising connecting one or more source/drain regions of corresponding one or more others of the multiple gates which need power supplies to one or more corresponding frontside BEOL wires, the one or more corresponding frontside BEOL wires connected to the frontside back end of line (BEOL) wire layer.

18. The method according to claim 15, wherein:
the gate is a first gate and the power supply rail is a first power supply rail;
the method further comprises:
forming a second power supply rail formed in the backside of the semiconductor wafer; and
forming another frontside BEOL wire layer connected to the second power supply rail through a second gate, wherein the second gate is of a type to be powered off by a power supply coupled through the second gate from the second power supply rail to the other frontside BEOL wire layer;
the first gate is an n-type gate and the power supply for the first gate is ground; and
the second gate is a p-type gate, and the power supply for the first gate is power.

19. The method according to claim 18, wherein forming the first and second gates comprise forming the first and second gates adjacent to each other and the method comprises forming and filling a gate cut between the adjacent first and second gates.

20. The method according to claim 15, further comprising:
forming a source/drain contact contacting a corresponding source/drain region and extending beyond the source/drain region to provide access to one of a signal track that is in a region between two doped regions of the same type and a signal track that is within the doped region.
